(19) United States
(12) Patent Application Publication
(10) Pub. No.: US 2019/0206867 A1
(43) Pub. Date: Jul. 4, 2019

(54) SEMICONDUCTOR DEVICE

(71) Applicant: Samsung Electronics Co., Ltd., Suwon-si (KR)

(72) Inventors: Jung Han LEE, Anyang-si (KR); Sungchul Park, Seongnam-si (KR); Yunil Lee, Anyang-si (KR); Byoung-gi Kim, Suwon-si (KR); Yeongmin Jeon, Hwaseong-si (KR); Daewon Ha, Seoul (KR); Inchan Hwang, Siheung-si (KR); Jae Hyun Park, Hwaseong-si (KR); Woocheol Shin, Seoul (KR)

(73) Assignee: Samsung Electronics Co., Ltd., Suwon-si (KR)

(21) Appl. No.: 16/030,224

(22) Filed: Jul. 9, 2018

(30) Foreign Application Priority Data
Dec. 29, 2017 (KR) 10-2017-0183370

(51) Int. Cl. H01L 27/092; H01L 29/423; H01L 27/02; H01L 29/08; H01L 21/8238; H01L 21/306; H01L 29/66; H01L 21/3213; H01L 21/02; H01L 29/78; H01L 29/165

(52) U.S. Cl. CPC H01L 27/0924; H01L 21/02532; H01L 27/0207; H01L 29/0847; H01L 21/823821; H01L 21/30604; H01L 21/823878; H01L 29/66545; H01L 21/823828; H01L 21/32139; H01L 29/6653; H01L 21/823864; H01L 21/823814; H01L 29/66636; H01L 21/02636; H01L 29/7848; H01L 29/165; H01L 21/02529; H01L 29/42372

(57) ABSTRACT

A semiconductor substrate includes a plurality of gate electrodes crossing active patterns on a substrate and extending in a second direction, the gate electrodes spaced apart in the second direction from each other, a gate separation pattern having a major axis in the first direction and between two of the gate electrodes, the two of the gate electrodes adjacent to each other in the second direction, and a plurality of gate spacers covering sidewalls of respective ones of the gate electrodes, the gate spacers crossing the gate separation pattern and extending in the second direction. The gate separation pattern includes a lower portion extending in the first direction, an intermediate portion protruding from the lower portion and having a first width, and an upper portion between two adjacent gate spacers and protruding from the intermediate portion, the upper portion having a second width less than the first width.

### CROSS-REFERENCE TO RELATED APPLICATIONS

This U.S. nonprovisional application claims priority under 35 U.S.C § 119 to Korean Patent Application No. 10-2017-0183370 filed on Dec. 29, 2017, in the Korean Intellectual Property Office, the entire contents of which are hereby incorporated by reference.

### BACKGROUND

Inventive concepts relate to a semiconductor device, and more particularly, to a semiconductor device including a field effect transistor.

A semiconductor device includes an integrated circuit consisting of metal oxide semiconductor field effect transistors (MOSFETs). As the semiconductor device becomes highly integrated, the scale down of the MOSFETs is also accelerated, and thus operating characteristics of the semiconductor device may deteriorate. Various researches have therefore been developed to fabricate a semiconductor device having superior performances while overcoming limitations due to the high integration of the semiconductor device.

### SUMMARY

Some example embodiments of inventive concepts provide a semiconductor device including highly-integrated field effect transistors.

Inventive concepts are not limited to the mentioned above, and other objects which have not been mentioned above will be clearly from the following description.

According to some example embodiments of inventive concepts, a semiconductor device may include a semiconductor substrate including active patterns extending in a first direction, a plurality of gate electrodes crossing the active patterns and extending in a second direction, the gate electrodes spaced apart in the second direction from each other, a gate separation pattern having a major axis in the first direction and between two of the gate electrodes, the two of the gate electrodes adjacent to each other in the second direction, and a plurality of gate spacers covering sidewalls of respective ones of the gate electrodes, the gate spacers crossing the gate separation pattern and extending in the second direction. The gate separation pattern includes a lower portion extending in the first direction, an intermediate portion protruding from the lower portion and having a first width, and an upper portion between two adjacent gate spacers and protruding from the intermediate portion, the upper portion having a second width less than the first width.

According to some example embodiments of inventive concepts, a semiconductor device may include a semiconductor substrate including active patterns extending in a first direction, a plurality of gate electrodes crossing the active patterns and extending in a second direction, the gate electrodes spaced apart in the second direction from each other, a gate separation pattern between at least two gate electrodes of the plurality of gate electrodes, the at least two gate electrodes adjacent to each other in the second direction, the gate separation pattern having a major axis in the first direction, and a plurality of gate spacers covering sidewalls of respective ones of the gate electrodes, the gate spacers crossing the gate separation pattern and extending in the second direction. The gate separation pattern includes an upper portion between two adjacent ones of the gate spacers, and a lower portion extending in the first direction below the gate spacers. Each of the gate spacers includes a low-k dielectric material having a dielectric constant less than that of the gate separation pattern.

According to some example embodiments of inventive concepts, a semiconductor device may a semiconductor substrate including a first active pattern and a second active pattern, the first active pattern and the second active pattern extending in a first direction, a plurality of first gate electrodes crossing the first active pattern and extending in a second direction, a plurality of second gate electrodes crossing the second active pattern and extending in the second direction, the second gate electrodes spaced apart from the first gate electrodes in the second direction, a gate separation pattern between one of the first gate electrodes and one of the second gate electrodes, the one of the first gate electrode and the one of the second gate electrode being adjacent to each other in the second direction, a plurality of gate spacers extending along the second direction from sidewalls of respective ones of the first gate electrodes and the second gate electrodes, a plurality of first epitaxial layers on the first active pattern and between the first gate electrodes, and a plurality of second epitaxial layers on the second active pattern and between the second gate electrodes. The gate separation pattern includes a plurality of first portions each having a first height between the one of the first gate electrodes and the one of the second gate electrodes, and a plurality of second portions connected in the first direction to the first portions and positioned in the second direction between one of the first epitaxial layers and one of the second epitaxial layers, wherein each of the second portions has a second height less than the first height.

Details of other example embodiments are included in the description and drawings.

### BRIEF DESCRIPTION OF THE DRAWINGS

FIG. 1 illustrates a simplified plan view showing a semiconductor device according to some example embodiments of inventive concepts.

FIGS. 2A to 12A illustrate plan views showing a method of fabricating a semiconductor device according to some example embodiments of inventive concepts.

FIGS. 2B to 12B, 2C to 12C, 2D to 12D, and 2E to 12E illustrate cross-sectional views taken along lines B-B′, C-C′, D-D′, and E-E′ of FIGS. 2A to 12A.

FIGS. 10F and 12F illustrate perspective views showing a method of fabricating a semiconductor device according to some example embodiments of inventive concepts.

FIGS. 13, 14, and 15 illustrate cross-sectional and plan views showing a method of fabricating a semiconductor device according to some example embodiments of inventive concepts.

FIGS. 16 and 17 illustrate cross-sectional views respectively taken along lines B-B′ and D-D′, respectively, of FIG. 15.

### DETAILED DESCRIPTION OF EXAMPLE EMBODIMENTS

A semiconductor device fabricating method and a semiconductor device fabricated by the same according to some example embodiments of inventive concepts will now be described with reference to the accompanying drawings.

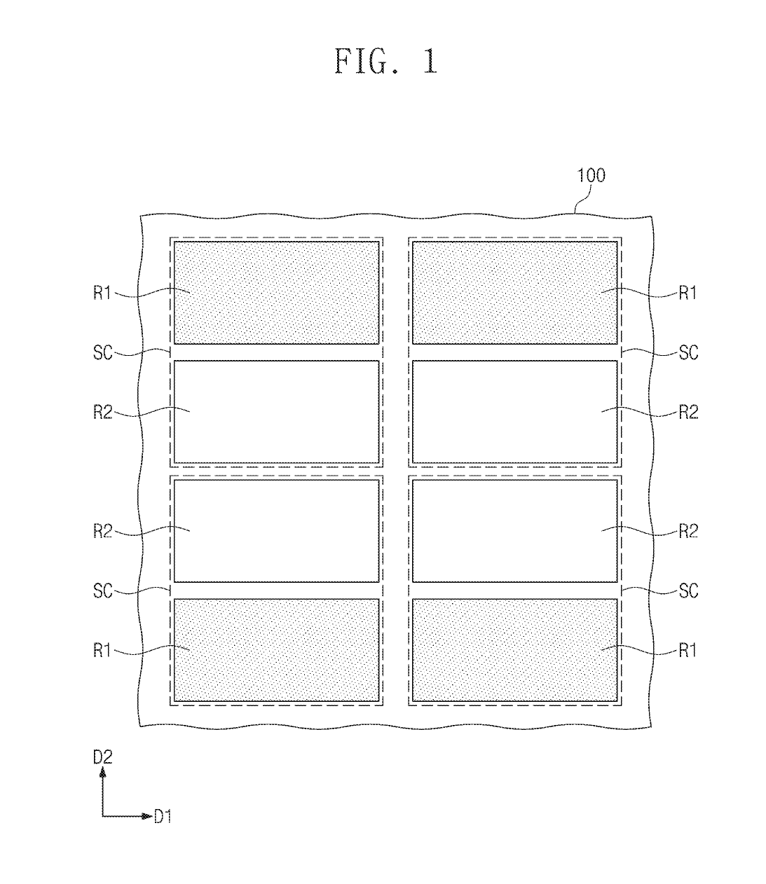

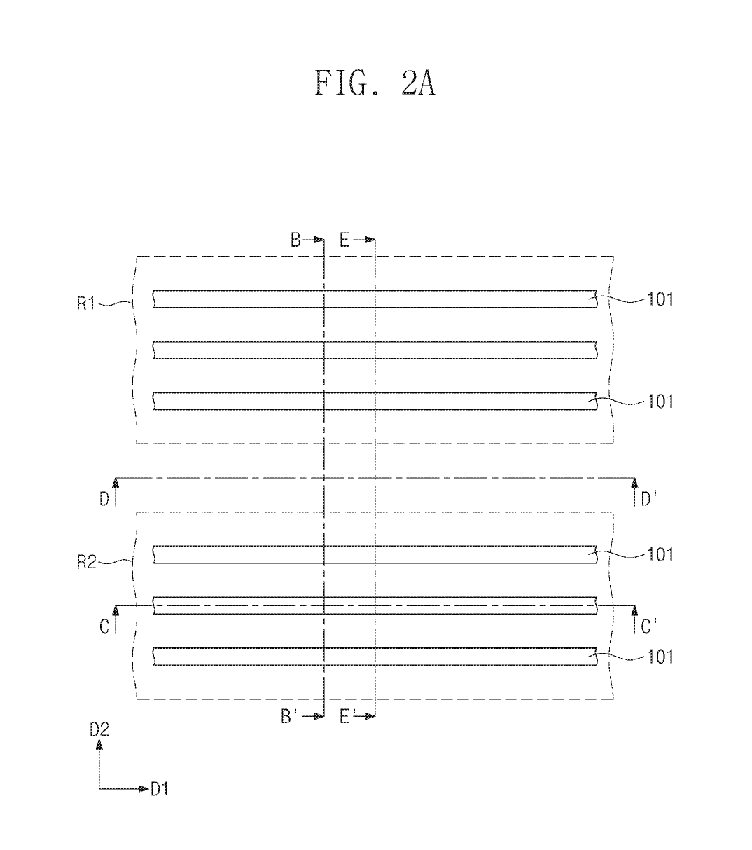

FIG. 1 illustrates a simplified plan view showing a semiconductor device according to some example embodiments of inventive concepts.

Referring to FIG. 1, a semiconductor substrate 100 may be provided thereon with integrated standard cells SC including logic devices such as a logical sum gate or a logical product gate. For example, the standard cells SC may include: a basic cell such as an AND gate, an OR gate, a NOR gate, and an inverter; a complex cell such as OAI (OR/AND/Inverter) gates and AOI (AND/OR/Inverter) gates; and/or a storage element such as a simple master-slave flip-flop and a latch.

A plurality of the standard cells SC may be two-dimensionally arranged along a first direction D1 and a second direction D2 intersecting the first direction D1. Each of the standard cells SC may include a first well region R1 where NMOS field effect transistors are formed and a second well region R2 where PMOS field effect transistors are formed.

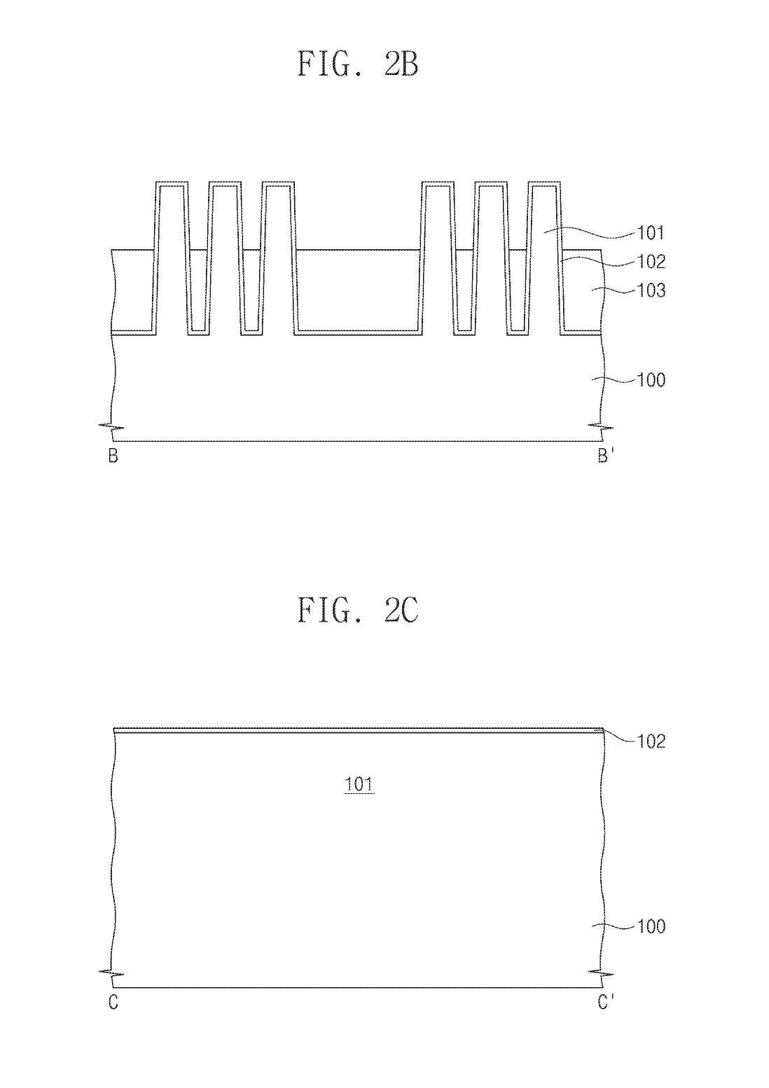

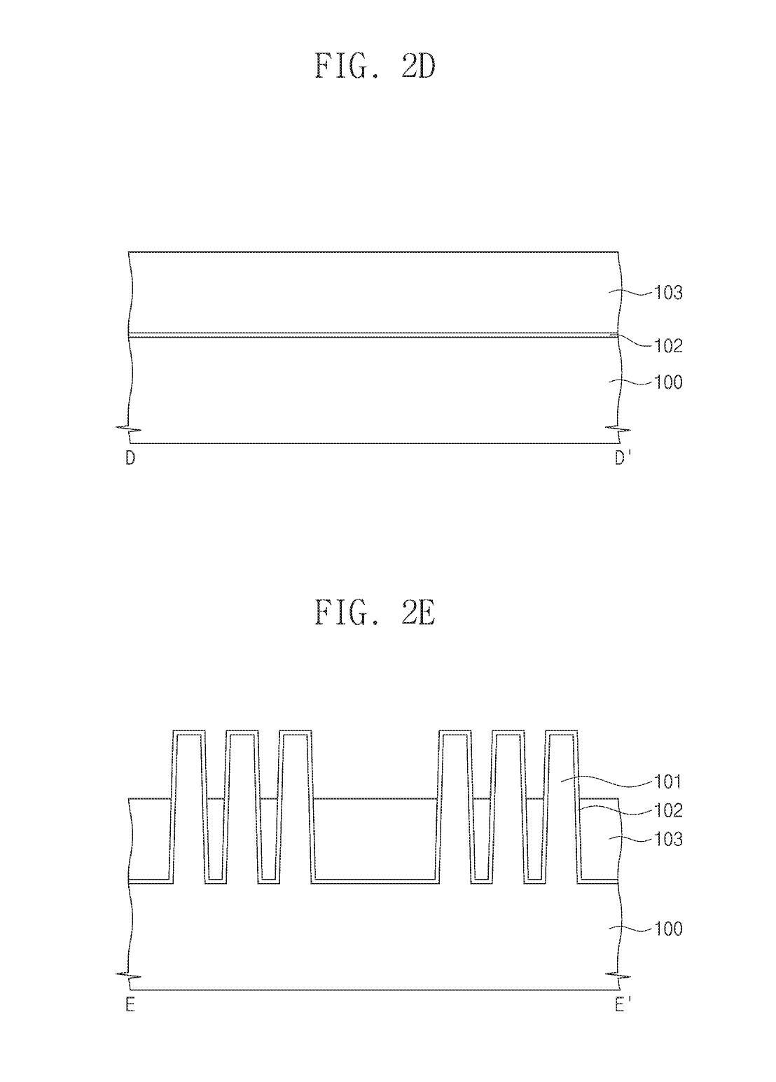

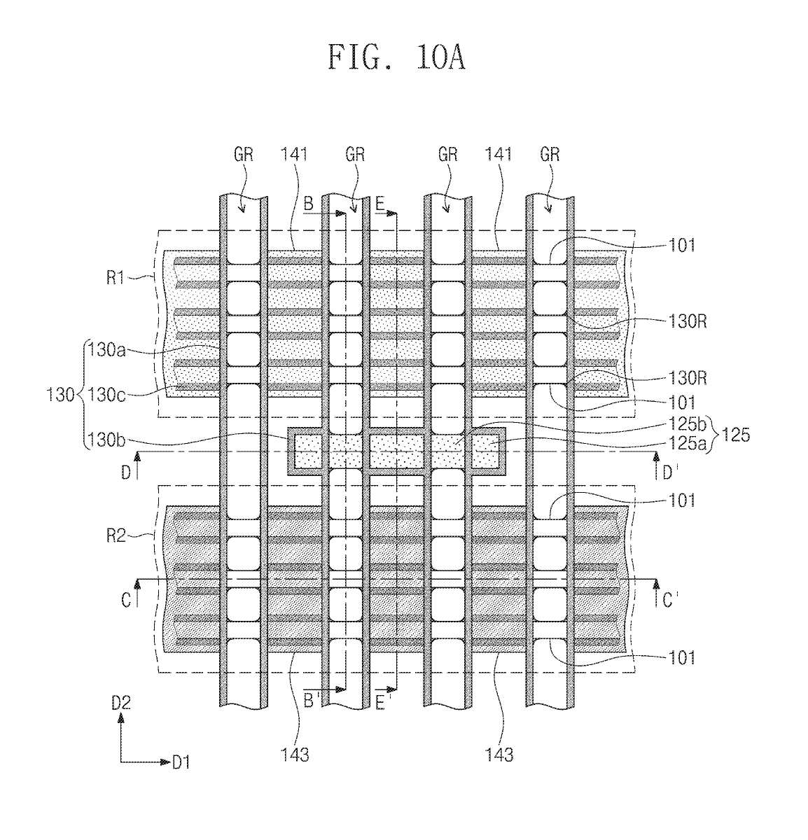

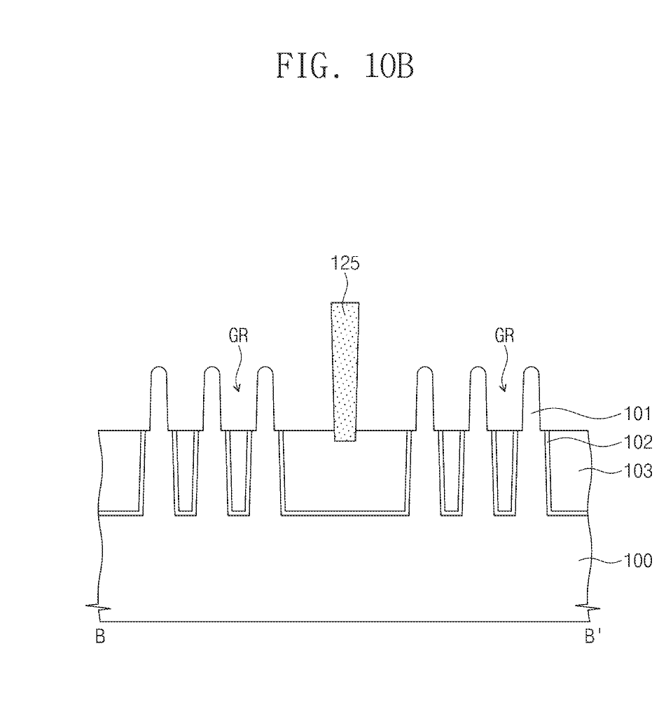

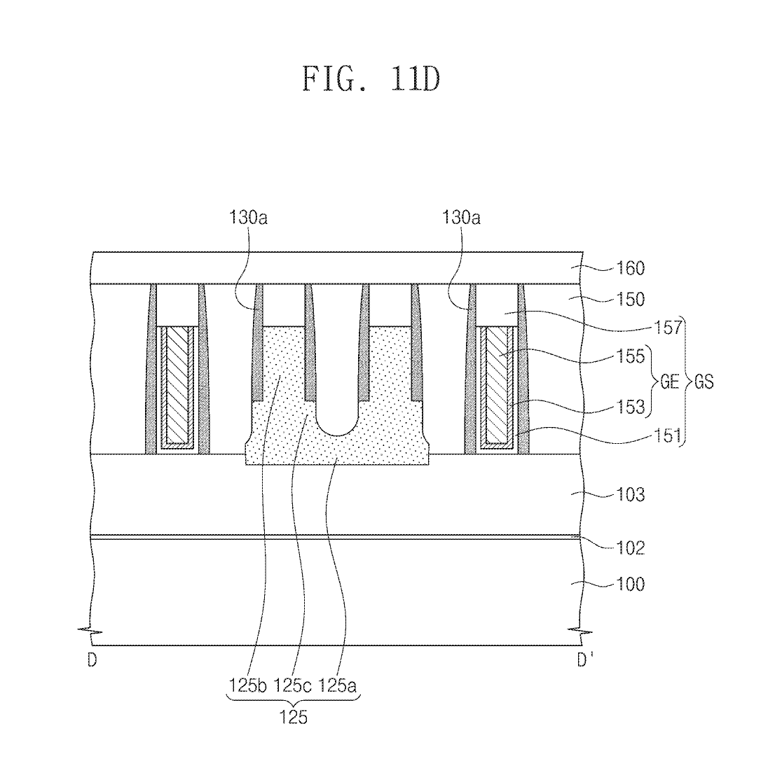

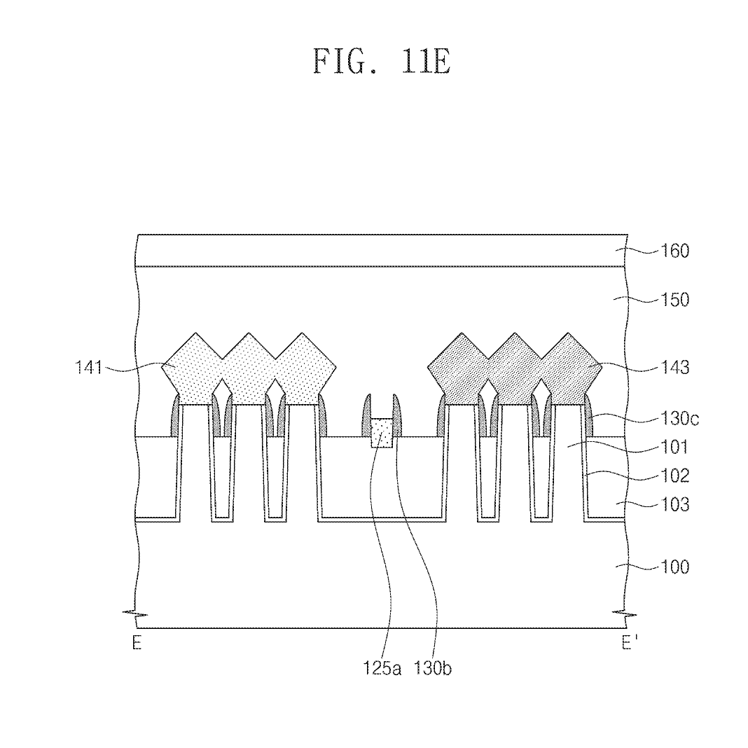

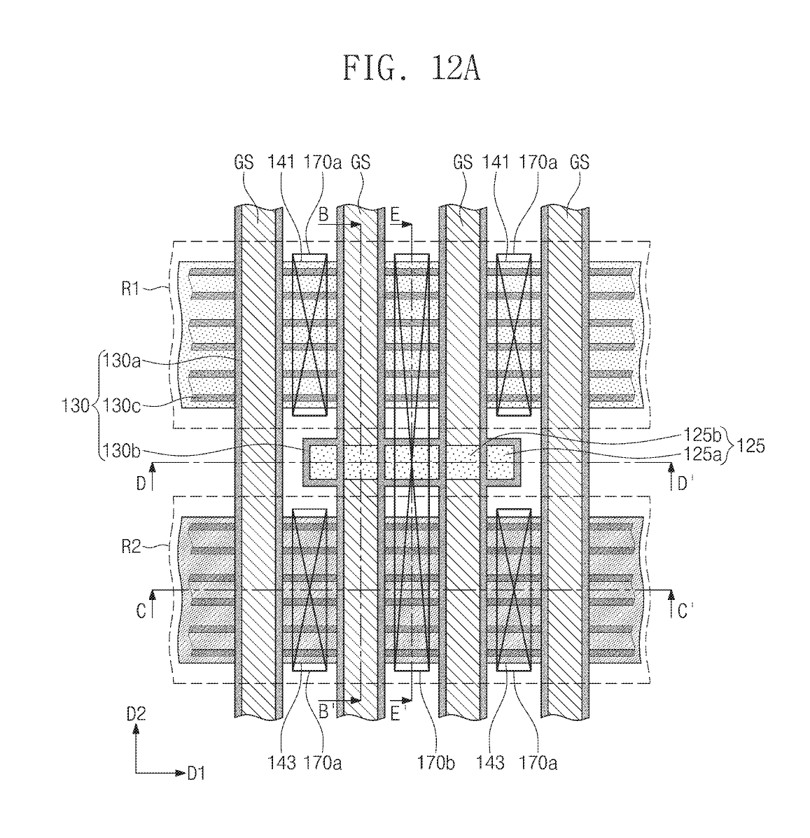

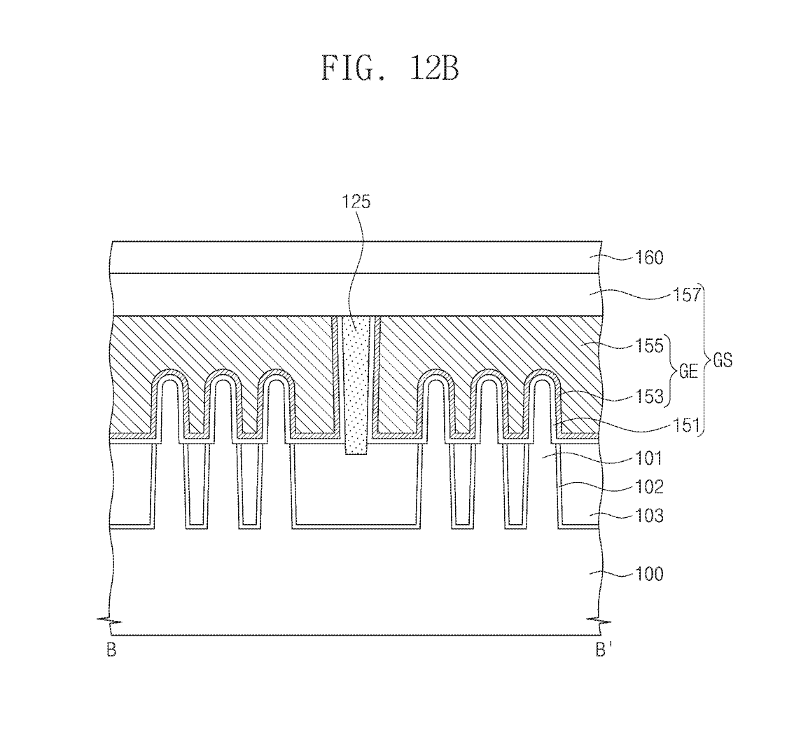

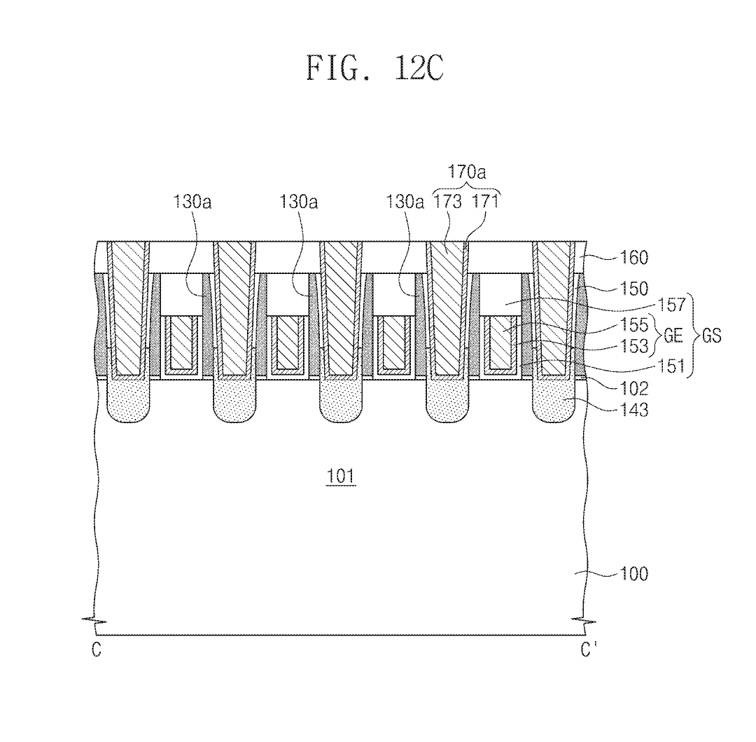

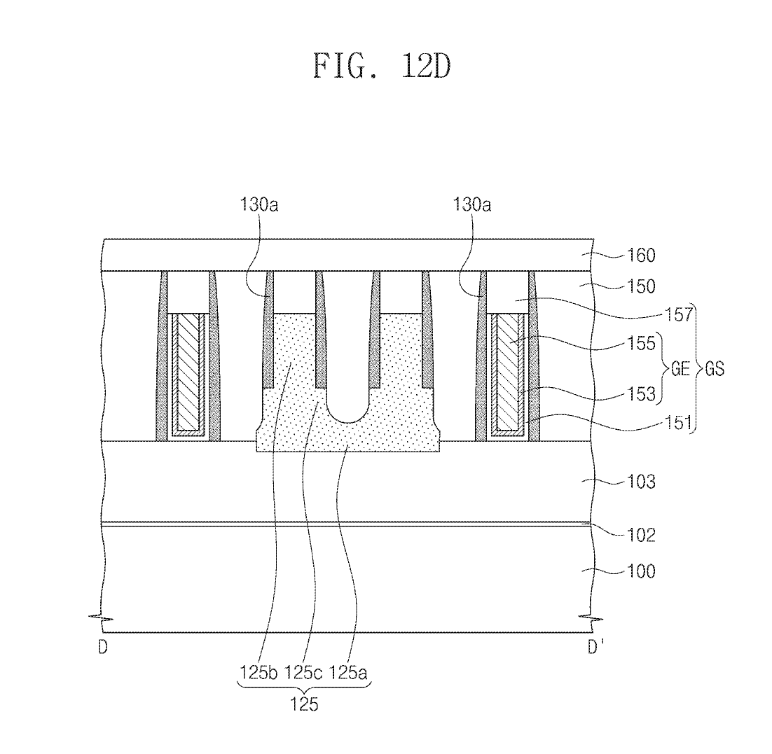

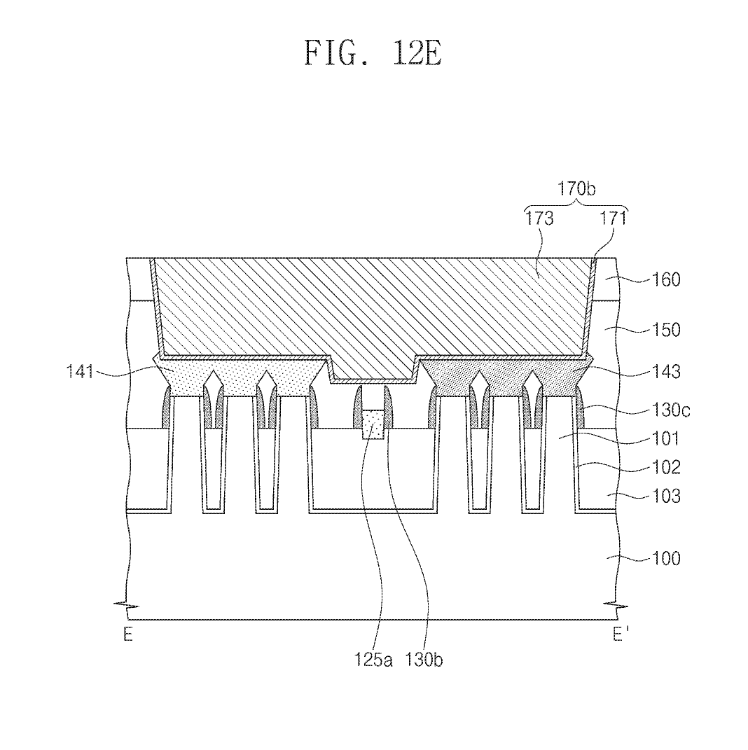

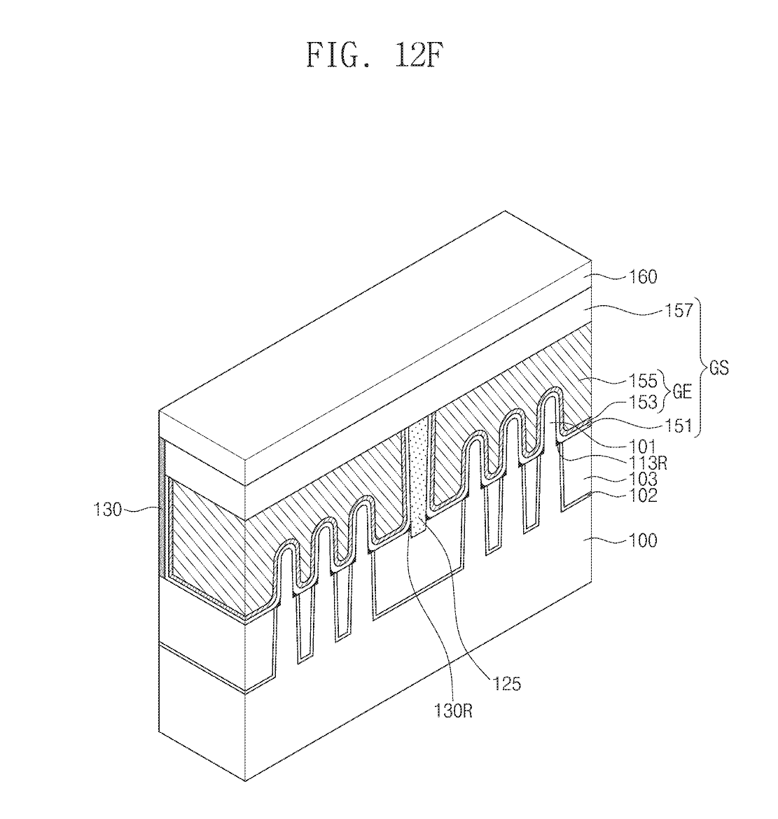

FIGS. 2A to 12A illustrate plan views showing a method of fabricating a semiconductor device according to some example embodiments of inventive concepts. FIGS. 2B to 12B, 2C to 12C, 2D to 12D, and 2E to 12E illustrate cross-sectional views along lines B-B′, C-C′, D-D′, and E-E′ of FIGS. 2A to 12A. FIGS. 10F and 12F illustrate perspective views showing a method of fabricating a semiconductor device according to some example embodiments of inventive concepts.

Referring to FIGS. 2A to 2E, a semiconductor substrate 100 may include first and second well regions R1 and R2. In some example embodiments, NMOS field effect transistors may be on the first well region R1, and PMOS field effect transistors may be on the second well region R2. The semiconductor substrate 100 may be, for example, a silicon substrate, a germanium substrate, a silicon-on-insulator (SOI) substrate, and/or a germanium-on-insulator (GOI) substrate.

The semiconductor substrate 100 may be patterned to form active patterns 101. On each of the first and second well regions R1 and R2A, a plurality of the active patterns 101 may extend in a first direction D1, and may be spaced apart from each other in a second direction D2 intersecting the first direction D1. In some example embodiments, the active patterns 101 may include first active patterns formed on the first well region R1 and second active patterns formed on the second well region R2.

The formation of the active patterns 101 may include forming a mask pattern (not shown) on the semiconductor substrate 100, and then anisotropically etching the semiconductor substrate 100 to form trenches. The active patterns 101 may be portions of the semiconductor substrate 100, and may be defined by the trenches formed on the semiconductor substrate 100. Each of the active patterns 101 may have a linear or bar shape whose major axis extends in the first direction D1, and may variously change in shape and arrangement.

A device isolation layer 103 may be formed between the active patterns 101. The device isolation layer 103 may have a top surface lower than those of the active patterns 101, and thus upper portions of the active patterns 101 may be exposed. The formation of the device isolation layer 103 may include forming an insulation layer to fill the trenches, planarizing the insulation layer to expose a top surface of the mask pattern, and recessing a planarized top surface of the insulation layer to expose upper sidewalls of the active patterns 101.

Before the device isolation layer 103 is formed, a buffer insulation layer 102 may be formed to conformally cover surfaces of the active patterns 101. The buffer insulation layer 102 may be formed of a silicon oxide layer, a silicon nitride layer, and/or a silicon oxynitride layer. The buffer insulation layer 102 may be formed by thermal oxidation, chemical vapor deposition (CVD), atomic layer deposition (ALD), and/or the like.

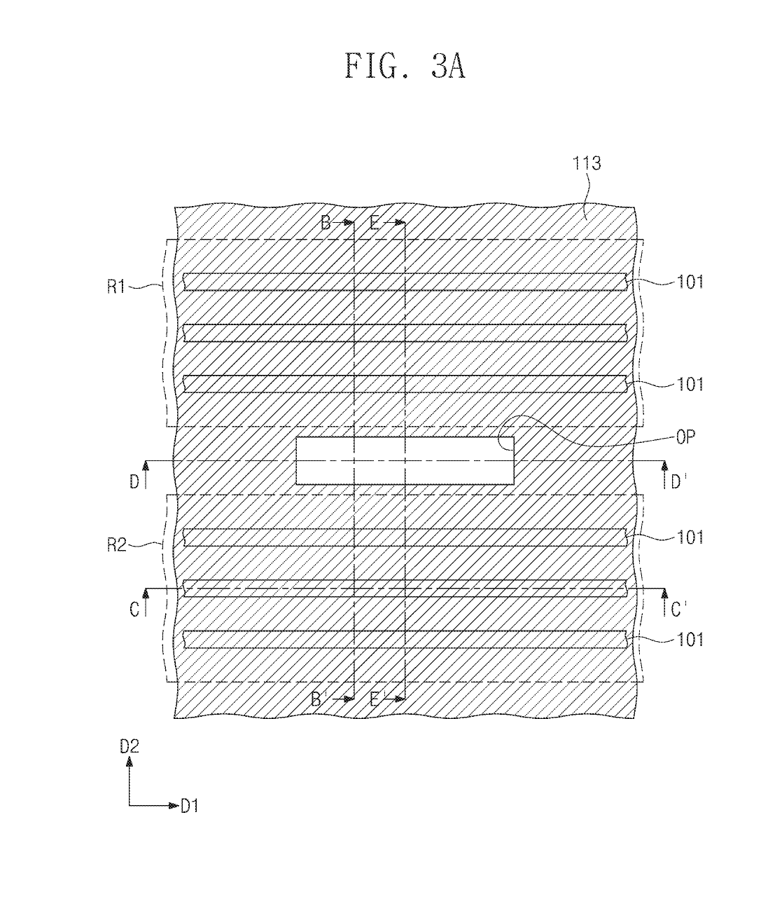

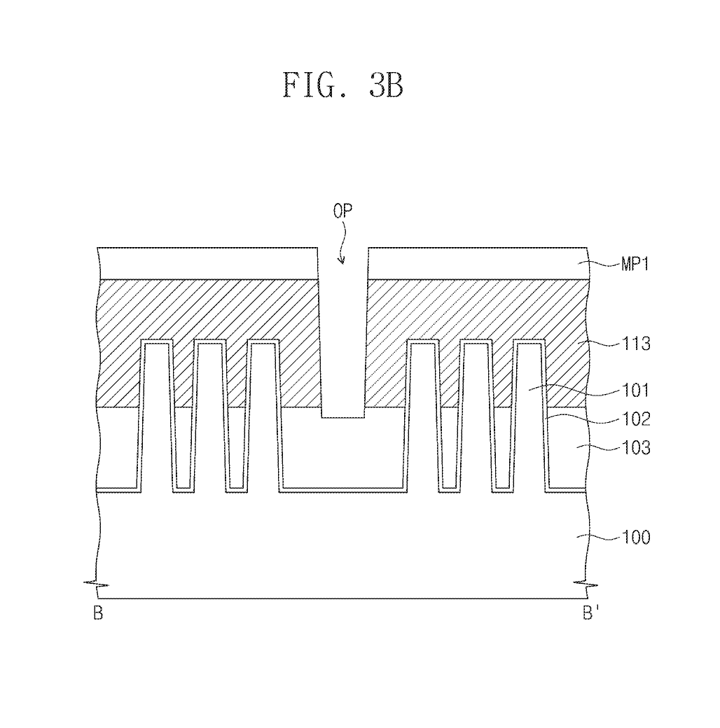

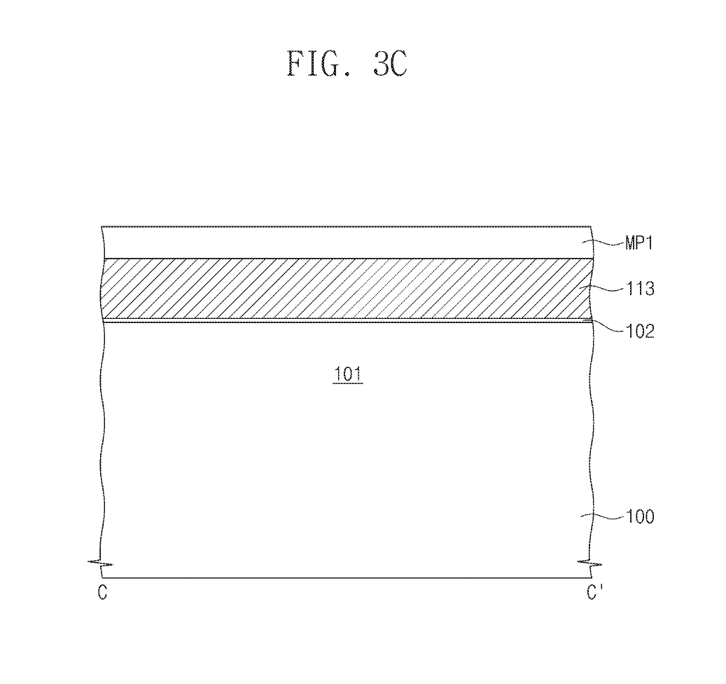

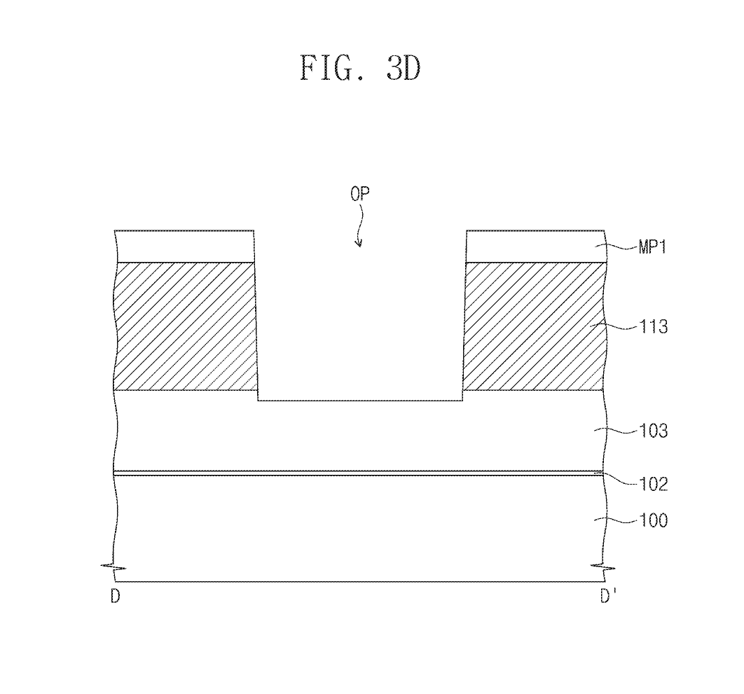

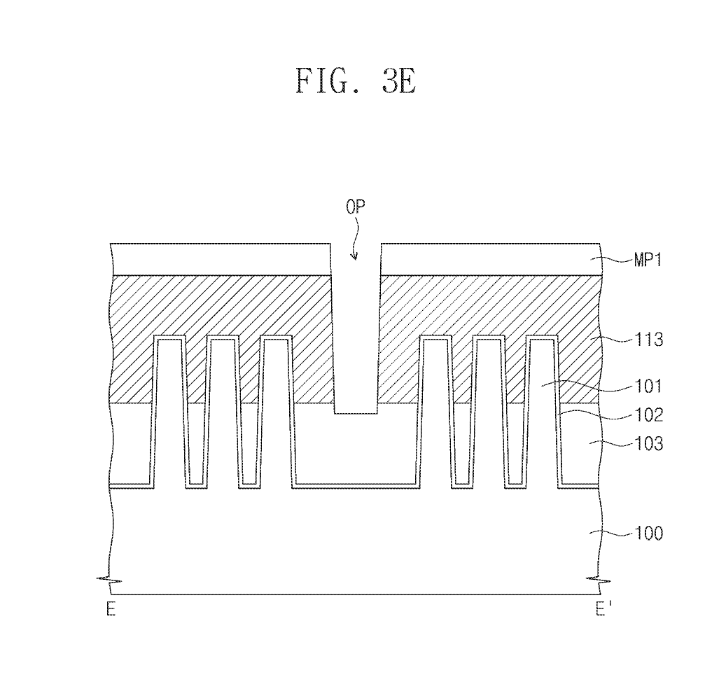

Referring to FIGS. 3A to 3E, a first dummy gate layer 113 may be formed to cover an entire surface of the semiconductor substrate 100 having the active patterns 101.

The first dummy gate layer 113 may fill between the active patterns 101, and may be formed of a material exhibiting etch selectivity to the buffer insulation layer 102, the device isolation layer 103, and the active patterns 101. For example, the first dummy gate layer 113 may be formed of an impurity-doped polysilicon layer, an undoped polysilicon layer, a silicon germanium layer, and/or a silicon carbide layer. The first dummy gate layer 113 may be formed by chemical vapor deposition (CVD), physical vapor deposition (PVD), atomic layer deposition (ALD), and/or the like, and a planarization process may be performed to give the first dummy gate layer 113 a flat top surface.

A first hardmask pattern MP1 may be formed on the first dummy gate layer 113. The first hardmask pattern MP1 may have an opening that partially exposes the first dummy gate layer 113. The first hardmask pattern MP1 may be formed of, e.g. include, a silicon nitride layer and/or a silicon oxynitride layer.

The first hardmask pattern MP1 may be used as an etching mask during anisotropically etching of the first dummy gate layer 113, which forms an opening OP that partially exposes the device isolation layer 103. In the anisotropic etching process for forming the opening OP, the device isolation layer 103 may serve as an etch stop layer. The anisotropic etching process may cause the opening OP to have an upper width and a lower width less than the upper width. For example, the opening OP may have a sidewall profile whose width gradually decreases toward the semiconductor substrate 100. In addition, in the anisotropic etching process for forming the opening OP, an over-etching may occur so that the device isolation layer 103 may be recessed on a portion exposed to the opening OP.

In some example embodiments, the opening OP may be between the first well region R1 and the second well region R2, and between the active patterns 101 adjacent in the second direction D2 to each other. The opening OP may have a bar shape whose major axis extends in the first direction D1. A length in the first direction D1 of the opening OP may be greater than widths of dummy gate patterns which will be formed in subsequent processes. Though only one opening OP is shown in figures, inventive concepts are not limited thereto, and a plurality of openings may be provided. The plurality of openings may have different shapes and/or sizes from each other.

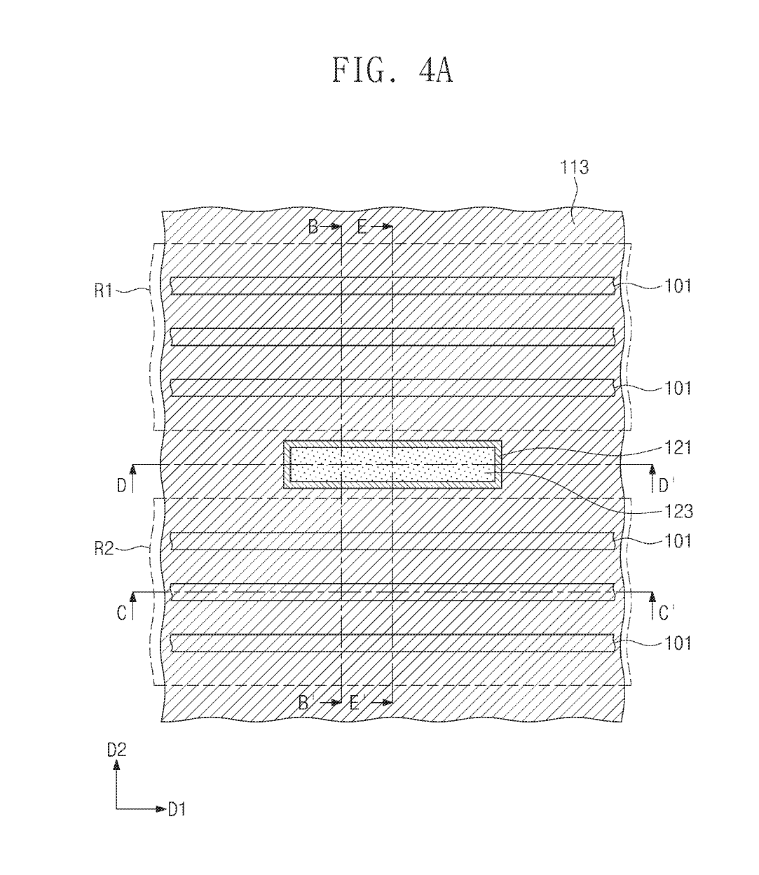

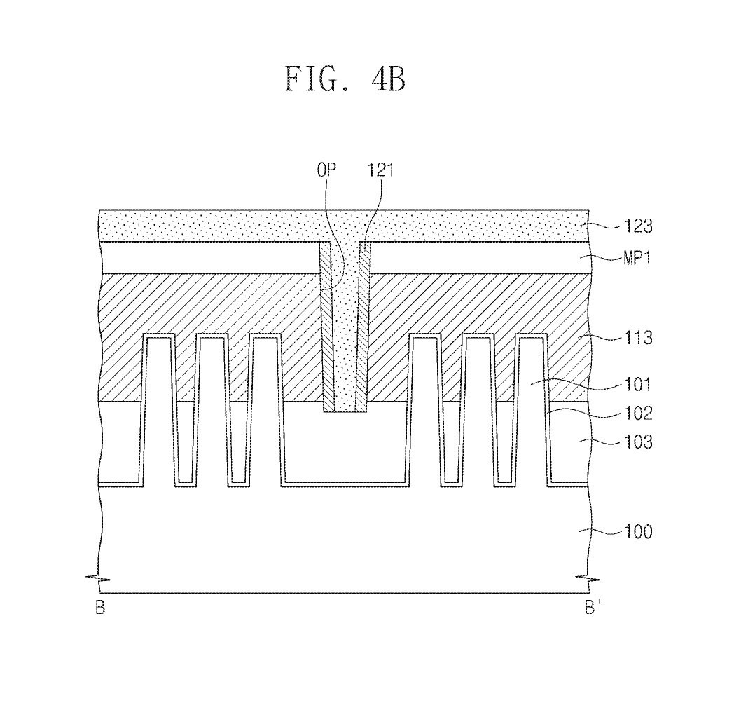

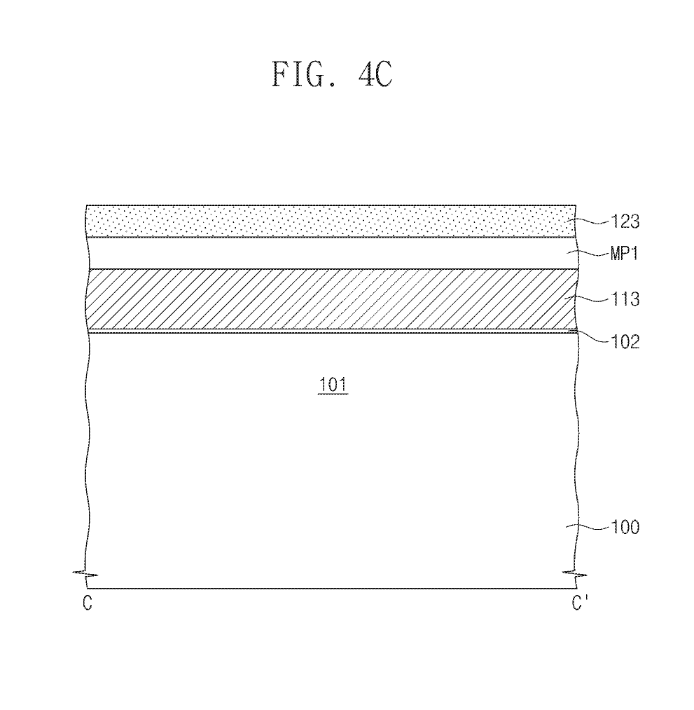

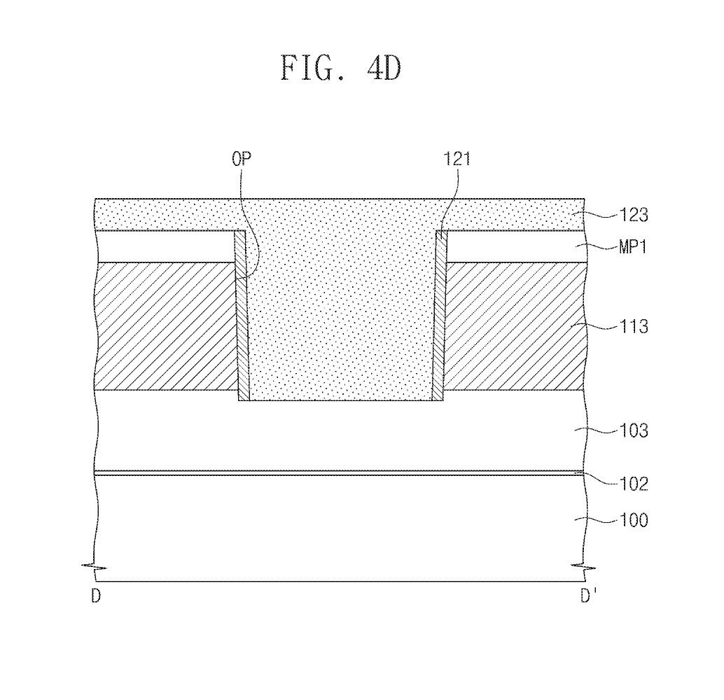

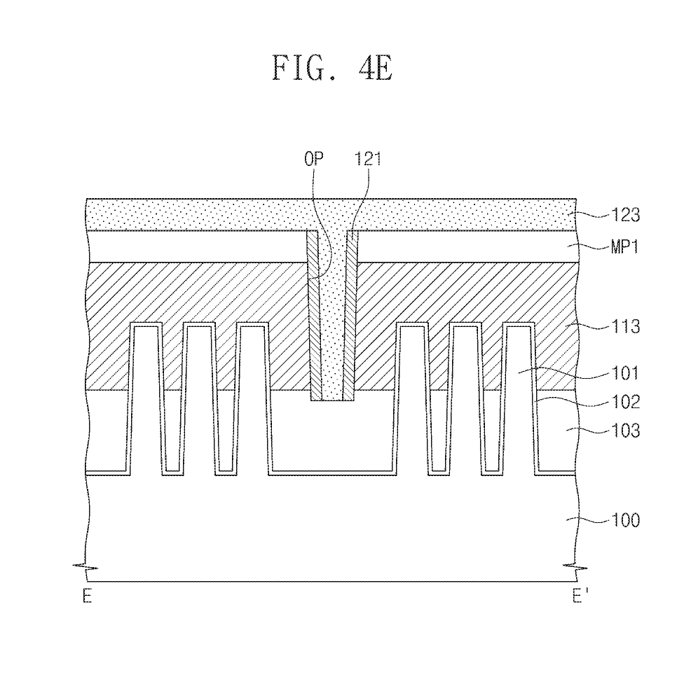

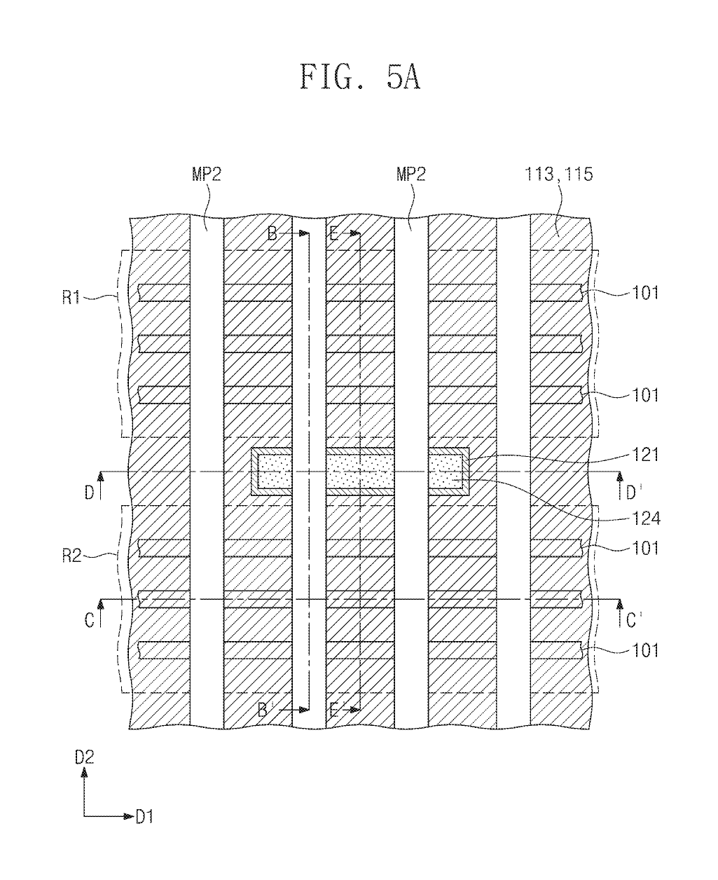

Referring to FIGS. 4A to 4E, a dummy spacer 121 may be formed to cover an inner wall of the opening OP. The formation of the dummy spacer 121 may include conformally depositing a dummy spacer layer on the first dummy gate layer 113 having the opening OP and exposing the device isolation layer 103 by performing an overall anisotropic etching process on the dummy spacer layer. The dummy spacer layer may have a thickness less than half a width of the opening OP. In some example embodiments, the dummy spacer 121 and the first dummy gate layer 113 may be formed of the same material, for example, a polysilicon layer. Alternatively, the dummy spacer 121 may be formed of a material exhibiting etch selectivity to the first dummy gate layer 113; for example, the dummy spacer 121 may be formed of a silicon oxide layer.

After the dummy spacer 121 is formed, a dielectric gate-separation layer 123 may be formed to fill the opening OP. The dielectric gate-separation layer 123 may be formed on the first hardmask pattern MP2 to completely fill the opening OP.

The dielectric gate-separation layer 123 may be formed of an insulating material exhibiting etch selectivity to the first dummy gate layer 113 and the dummy spacer 121. The dielectric gate-separation layer 123 may include one or more of a silicon oxide layer, a silicon nitride layer, a silicon oxynitride layer, and a low-k dielectric layer. The dielectric gate-separation layer 123 may be formed by chemical vapor deposition (CVD), atomic layer deposition (ALD), and/or the like.

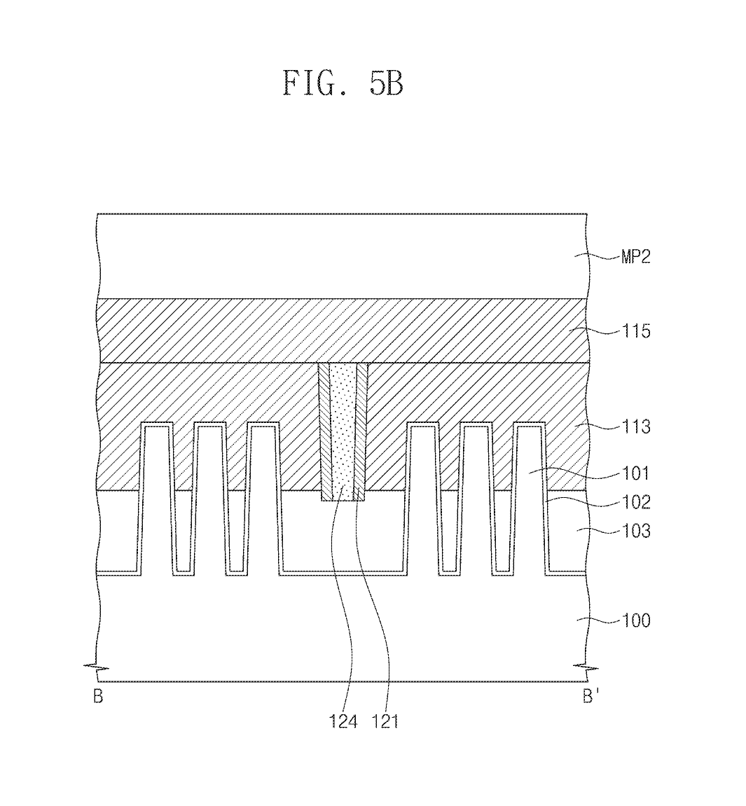

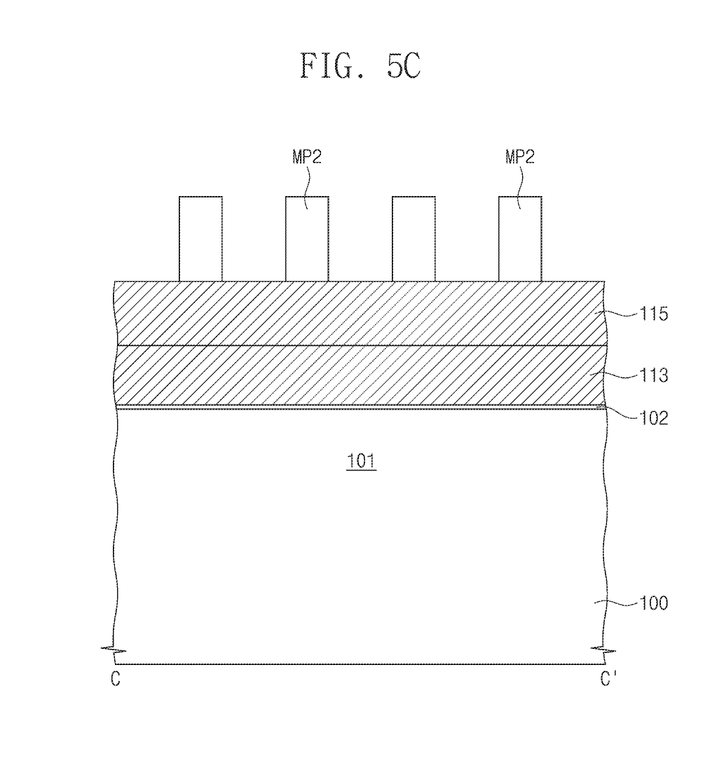

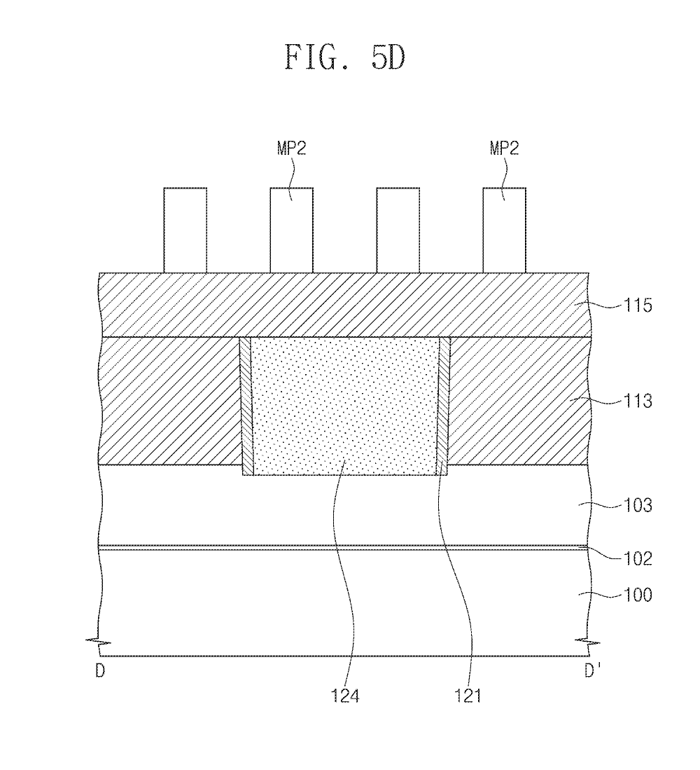

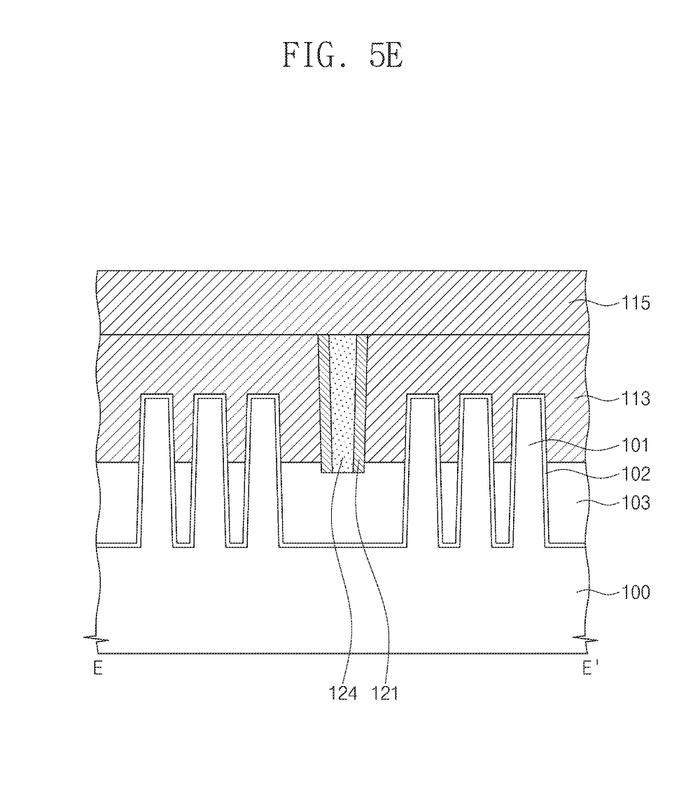

Referring to FIGS. 5A to 5E, a planarization process may be performed on the dielectric gate-separation layer 123 to expose the first dummy gate layer 113, thereby forming a preliminary gate-separation pattern 124. In some example embodiments, the first hardmask pattern MP1 may be removed during the formation of the preliminary gate-separation pattern 124. After the preliminary gate-separation pattern 124 is formed, the first dummy gate layer 113 may have a top surface at substantially the same level as those of top surfaces of the dummy spacer 121 and the preliminary gate-separation pattern 124. The preliminary gate-separation pattern 124 may have a bottom surface lower than that of the first dummy gate layer 113, or than the top surface of the device isolation layer 103.

The preliminary gate-separation pattern 124 may be on the device isolation layer 103 between the first and second well regions R1 and R2, and may have a bar shape whose major axis extends in the first direction D1. The dummy spacer 121 may surround a sidewall of the preliminary gate-separation pattern 124. A width in the second direction D2 of the preliminary gate-separation pattern 124 may be less than the width of the opening OP, and may vary depending on a thickness of the dummy spacer 121.

A second dummy gate layer 115 may be formed to cover the entire surface of the semiconductor substrate 100. For example, the second dummy gate layer 115 may cover the first dummy gate layer 113, the dummy spacer 121, and the preliminary gate-separation pattern 124. In some example embodiments, the second dummy gate layer 115 and the first dummy gate layer 113 may include the same material (e.g., polysilicon).

The second dummy gate layer 115 may be provided thereon with second hardmask patterns MP2 each of which has a linear shape extending in the second direction D2. One or more of the second hardmask patterns MP2 may cross over the preliminary gate-separation pattern 124.

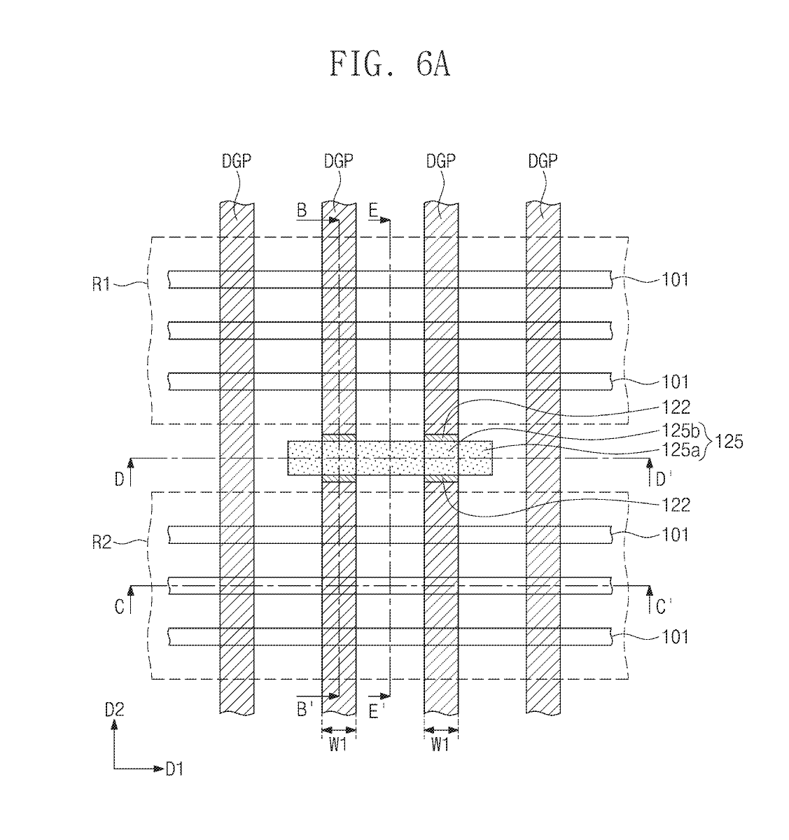

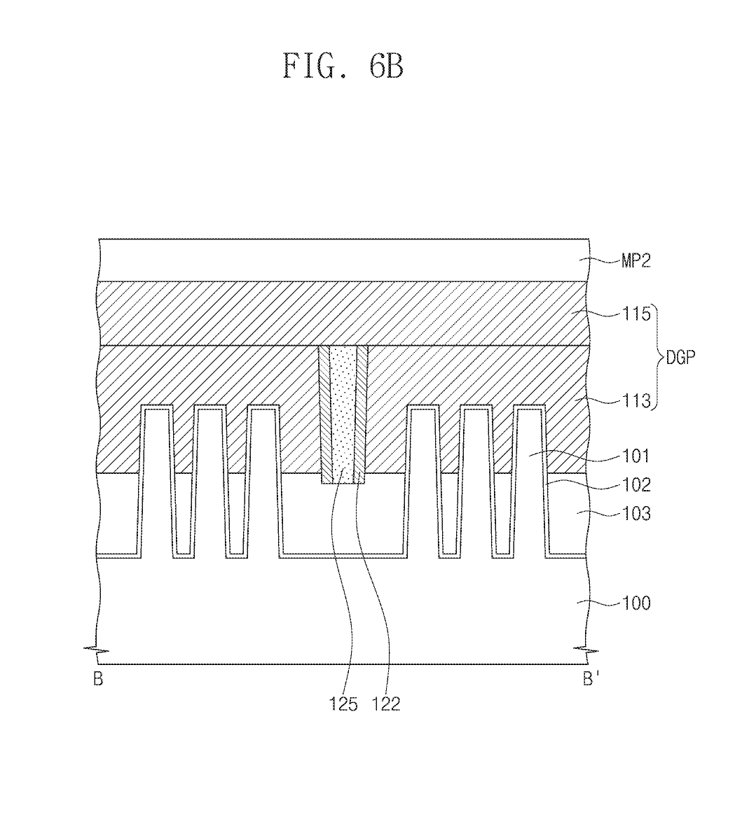

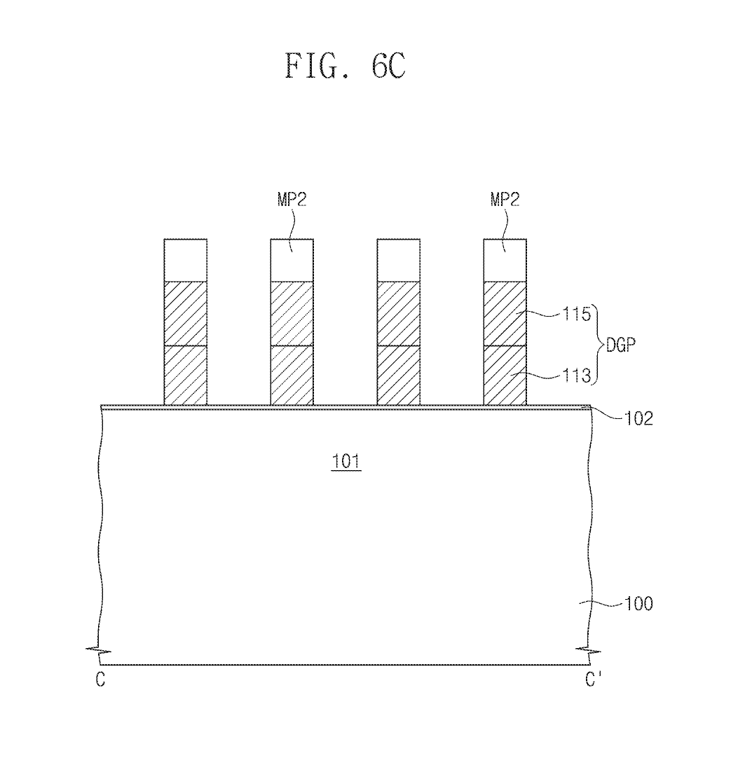

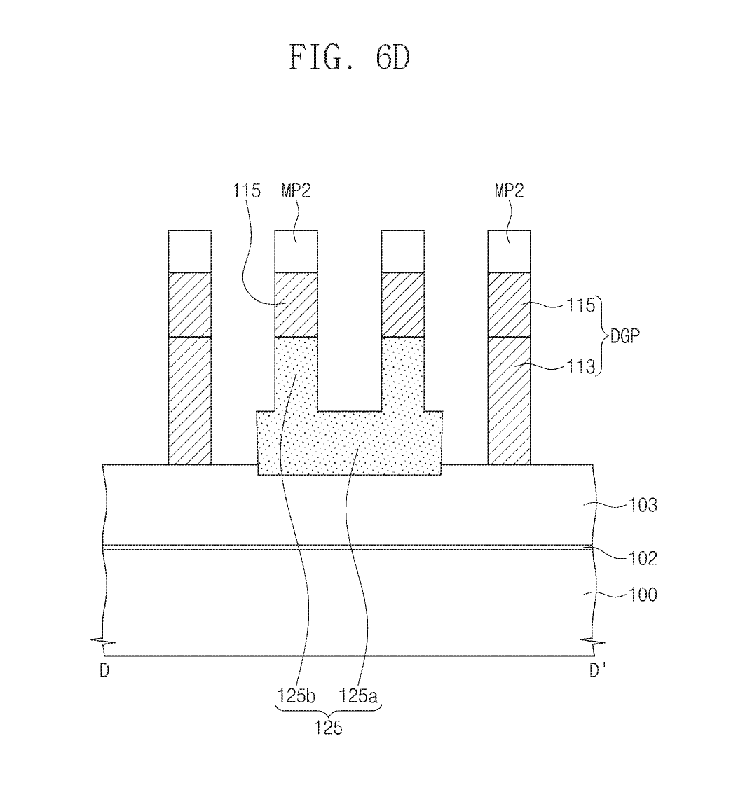

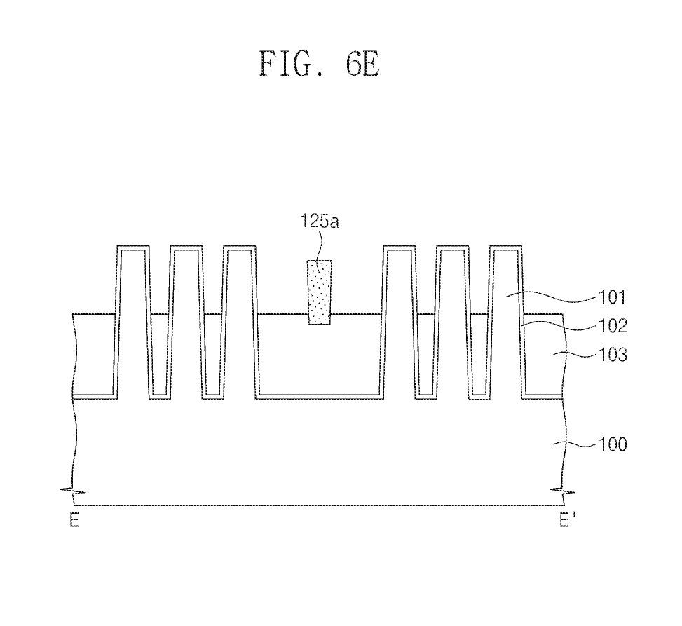

Referring to FIGS. 6A to 6E, the second hardmask patterns MP2 may be used as an etching mask to sequentially and anisotropically etching the first and second dummy gate layers 113 and 115 and the preliminary gate-separation pattern 124, which etching process may form dummy gate patterns DGP and a gate separation pattern 125.

The dummy gate patterns DGP may be spaced apart from each other in the first direction D1 and extend in the second direction D2 to cross the active patterns 101. The gate separation pattern 125 may separate ones of the dummy gate patterns DGP from each other in the second direction D2. In some example embodiments, each of the dummy gate patterns DGP may include the first and second dummy gate layers 113 and 115 that are patterned.

In the anisotropic etching process for forming the dummy gate patterns DGP, the preliminary gate-separation pattern 124 may be recessed on a top surface exposed between the second hardmask patterns MP2 such that the gate separation pattern 125 may be formed.

For example, as illustrated in FIGS. 6D and 6E, the gate separation pattern 125 may include a lower portion 125a extending in the first direction D1 and crossing at least two dummy gate patterns DGP and also include upper portions 125b protruding from the lower portion 125a. The lower portion 125a may have a top surface at a lower level than those of top surfaces of the upper portions 125b. Accordingly, the gate separation pattern 125 may have a larger height between the dummy gate patterns DGP adjacent in the second direction D2 to each other and a smaller height between the dummy gate patterns DGP adjacent in the first direction D1 to each other. Each of the upper portions 125b of the gate separation pattern 125 may be between the dummy gate patterns DGP adjacent in the second direction D2 to each other. The upper portions 125b of the gate separation pattern 125 may have a width W1 the same as those of the dummy gate patterns DGP.

In addition, in the anisotropic etching process for forming the dummy gate patterns DGP, the dummy spacer 121 may be etched on its portion exposed between the second hardmask patterns MP2. Therefore, dummy spacer patterns 122 may be locally formed between the dummy gate patterns DGP and the upper portions 125b of the gate separation pattern 125.

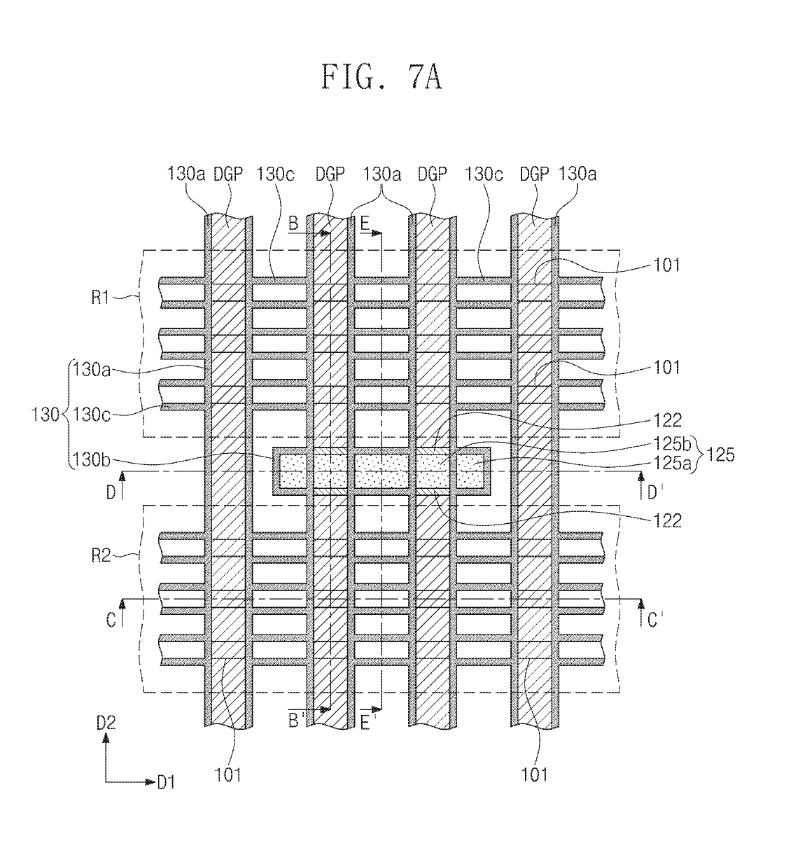

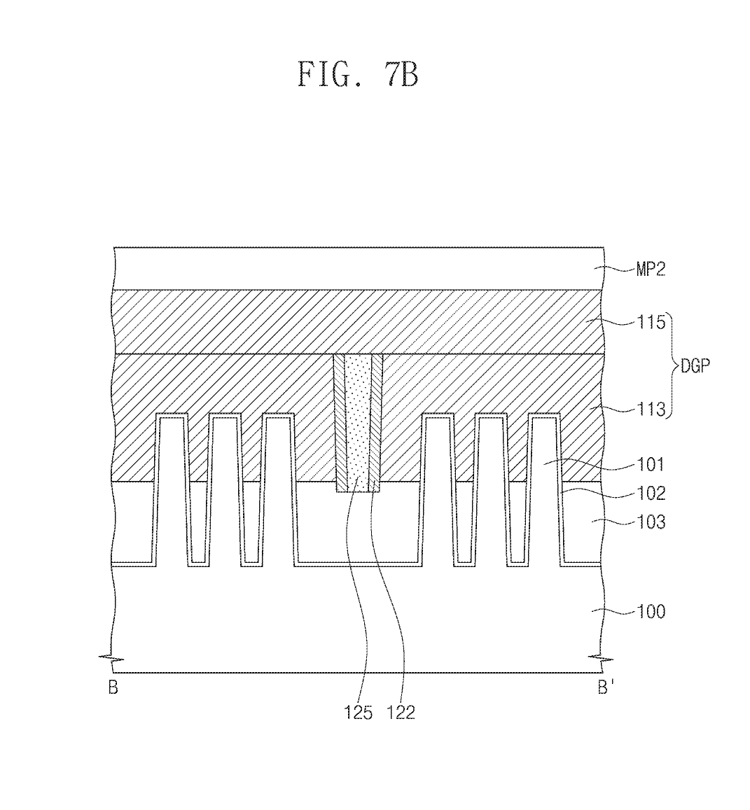

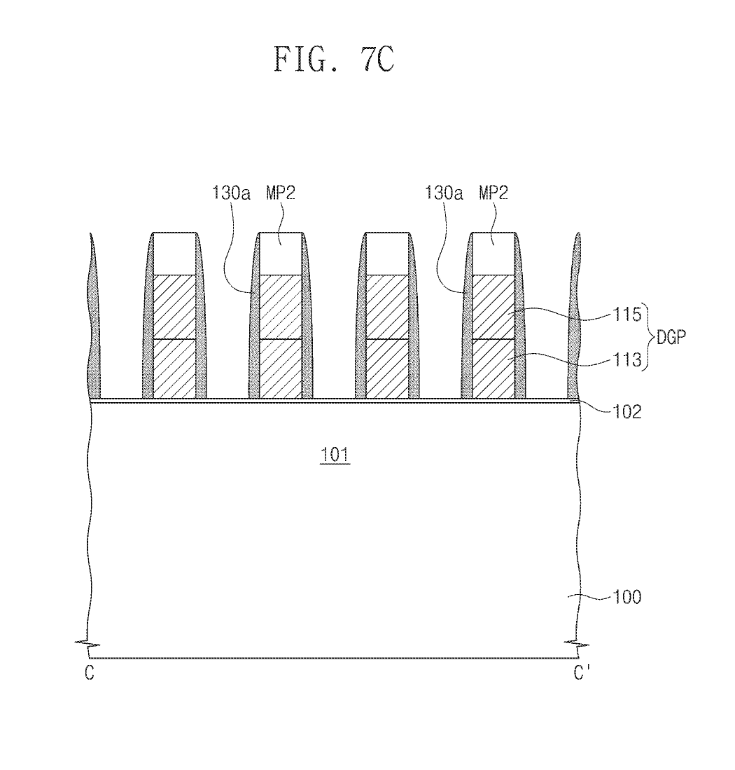

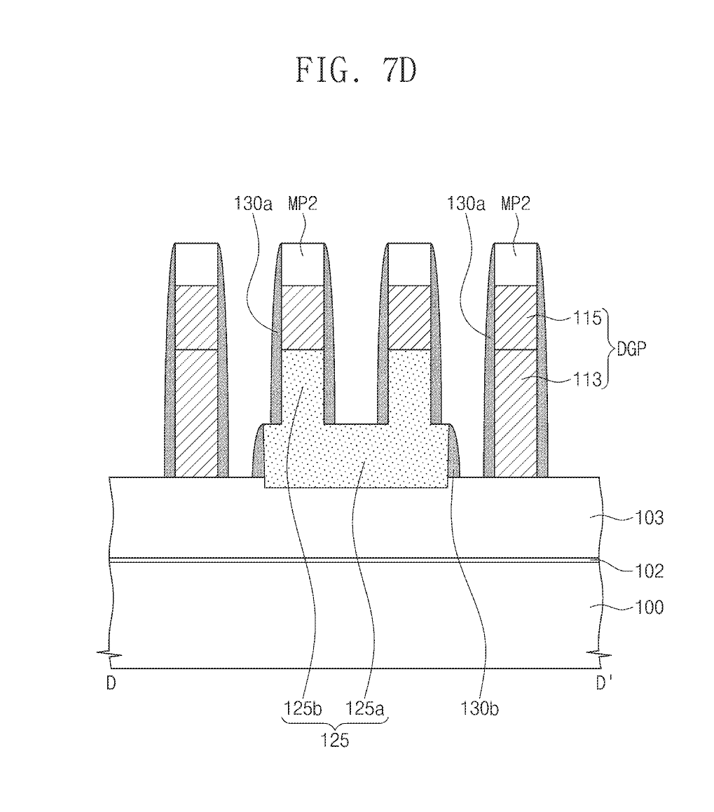

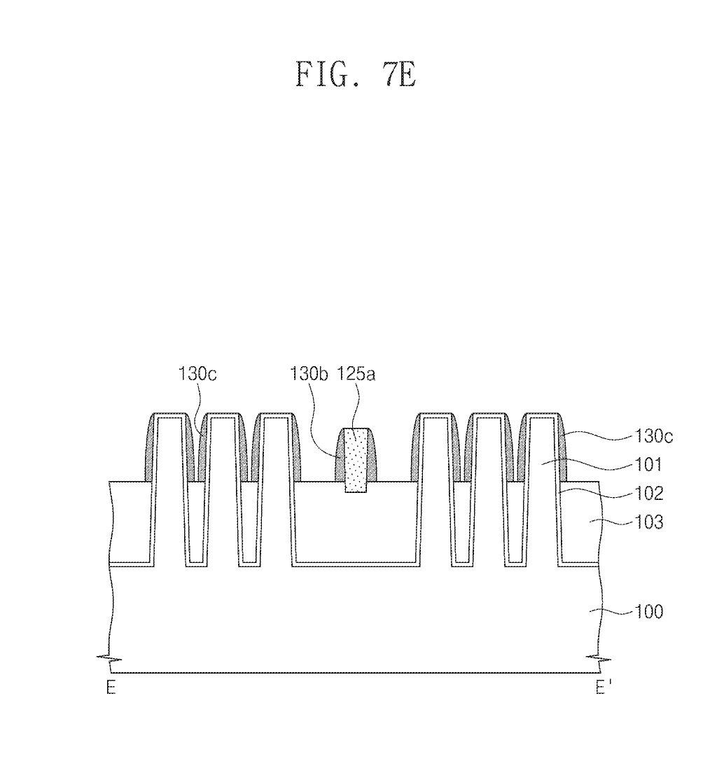

Referring to FIGS. 7A to 7E, gate spacers 130 may be formed to cover opposite sidewalls of each of the dummy gate patterns DGP. The gate spacers 130 may also be formed on sidewalls of the gate separation pattern 125 and sidewalls of the active patterns 101.

The formation of the gate spacers 130 may include conformally depositing a gate spacer layer on the semiconductor substrate 100 on which the active patterns 101, the dummy gate patterns DGP, and the gate separation pattern 125 are formed, and performing an overall anisotropic etching process on the gate spacer layer.

The gate spacers 130 may be formed of an insulating material exhibiting etch selectivity to the active patterns 101, the dummy gate patterns DGP, and the gate separation pattern 125. In some example embodiments, the gate spacers 130 may be formed of a low-k dielectric material whose dielectric constant is less than that of the gate separation pattern 125. The gate spacers 130 may include an insulating material such as SiC, SiCN, SiOCH, SiOC, and SiOF. The gate spacers 130 may have a dielectric constant ranging from about 1.0 to about 3.0, and may include one or more of an inorganic material, an organic material, and an organic-inorganic hybrid material. Alternatively or additionally, the gate spacers 130 may include a porous or nonporous dielectric material.

For example, the gate spacers 130 may include a first spacer portion 130a, a second spacer portion 130b, and a third spacer portion 130c. The first spacer portion 130a may extend along the second direction D2 and cross the gate separation pattern 125. The second spacer portion 130b may extend along the first direction D1 and cover a sidewall of the lower portion 125a of the gate separation pattern 125. The third spacer portion 130c may extend along the first direction D1 and cover the sidewalls of the active patterns 101 The first spacer portion 130a of the gate spacers 130 may cover sidewalls of the dummy gate patterns DGP spaced apart in the second direction D2 from each other and sidewalls of the upper portions 125b of the gate separation pattern 125. The first spacer portion 130a of the gate spacers 130 may be on the lower portion 125a of the gate separation pattern 125. The first spacer portion 130a of the gate spacers 130 may have a height greater than that of the second spacer portion 130b of the gate spacers 130.

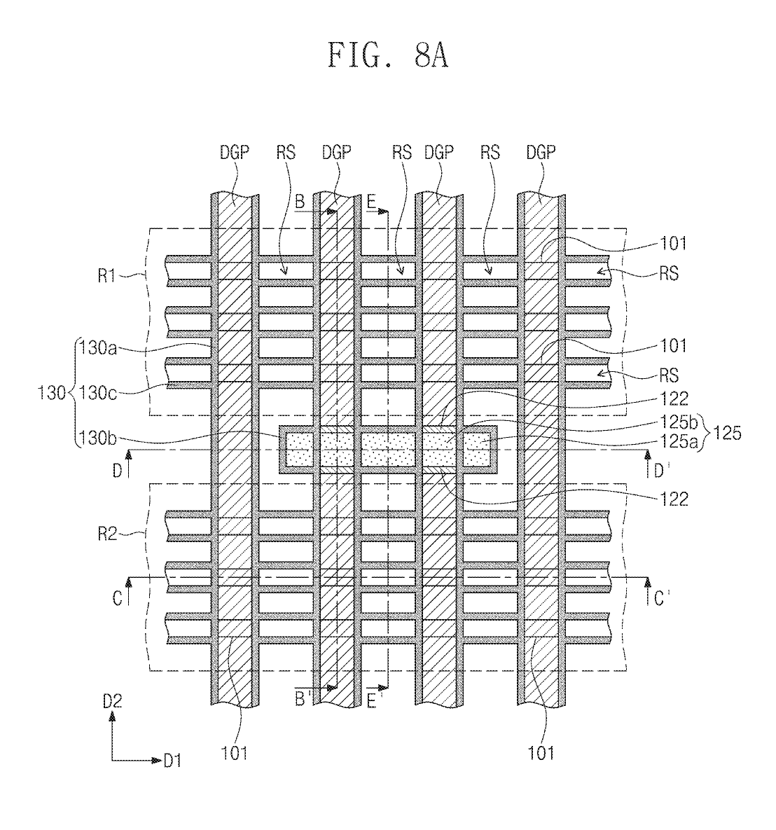

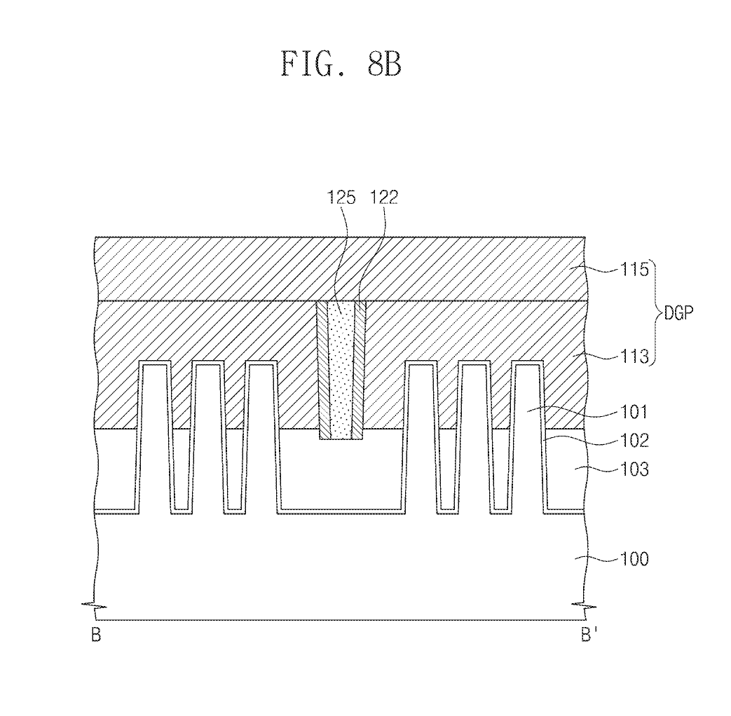

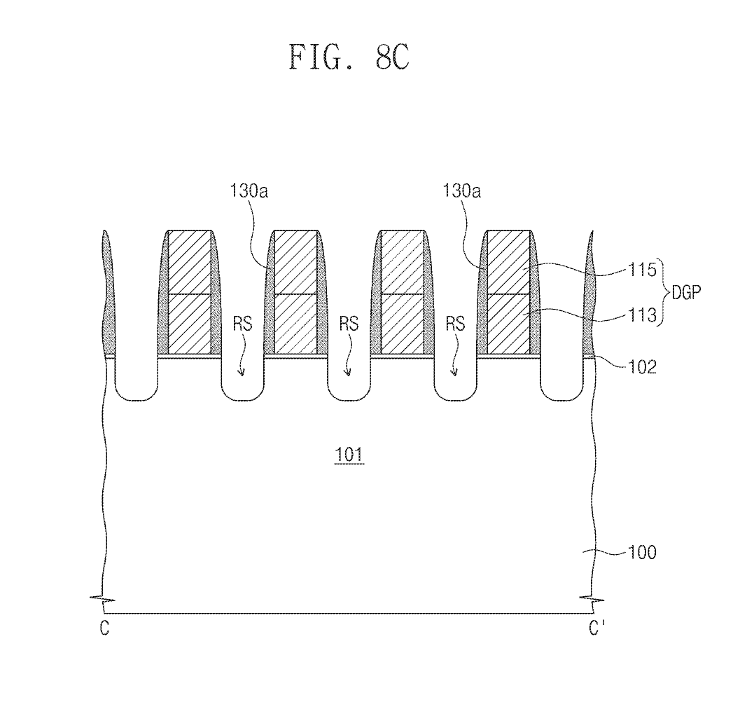

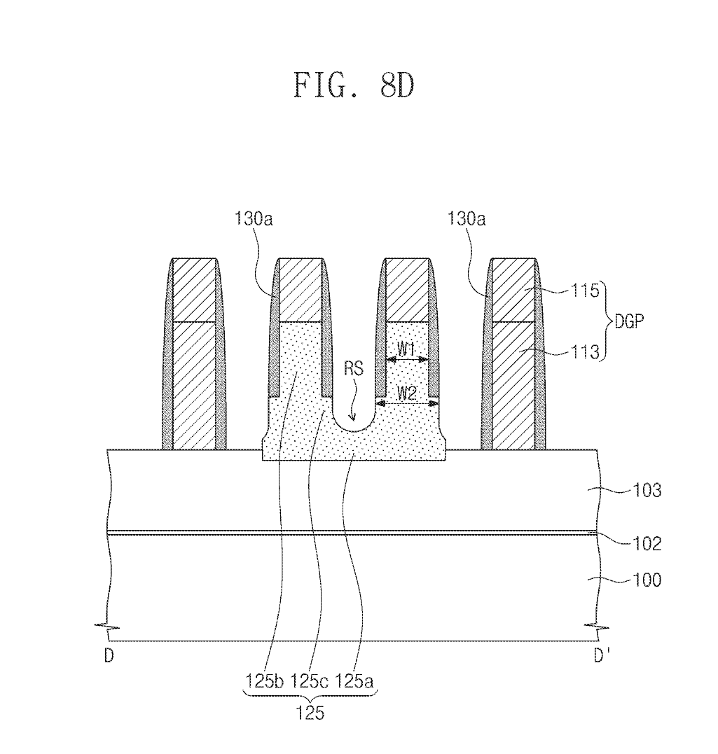

Referring to FIGS. 8A to 8E, after the gate spacers 130 are formed, recessions RS may be formed on the active patterns 101 on opposite sides of each of the dummy gate patterns DGP. The recessions RS may be formed when the buffer insulation layer 102 is etched on its portion exposed between the gate spacers 130 and the active patterns 101 are etched on their portions exposed between the gate spacers 130. The recessions RS may be formed by performing an anisotropic and/or isotropic etching processes each in which the dummy gate patterns DGP and the gate spacers 130 are used as an etching mask.

As illustrated in FIGS. 8D and 8E, in some example embodiments, during the etching process for forming the recessions RS, the etching process may also be performed on the gate separation pattern 125 such that the lower portion 125a may be etched on its portion exposed between the gate spacers 130. The top surface of the lower portion 125a of the gate separation pattern 125 may then be recessed to form an intermediate portion 125c between the lower and upper portions 125a and 125b of the gate separation pattern 125. The intermediate portion 125c of the gate separation pattern 125 may be placed below the first spacer portion 130a of the gate spacers 130, and may have a width W2 greater than the width W1 of the upper portion 125b. The lower portion 125a of the gate separation pattern 125 may have a height dependent on etching conditions under which the recessions RS are formed. In the etching process for forming the recessions RS, the second hardmask pattern MP2 may decrease in thickness or may be removed.

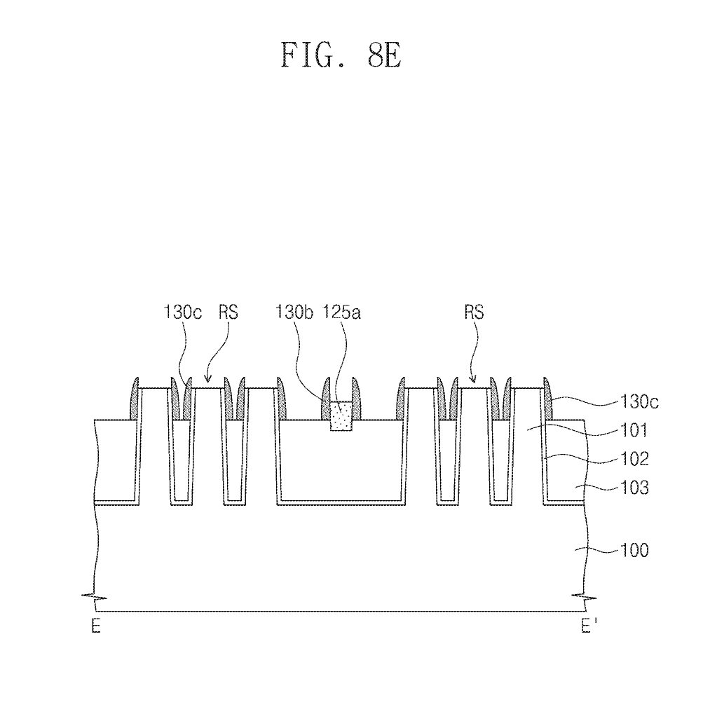

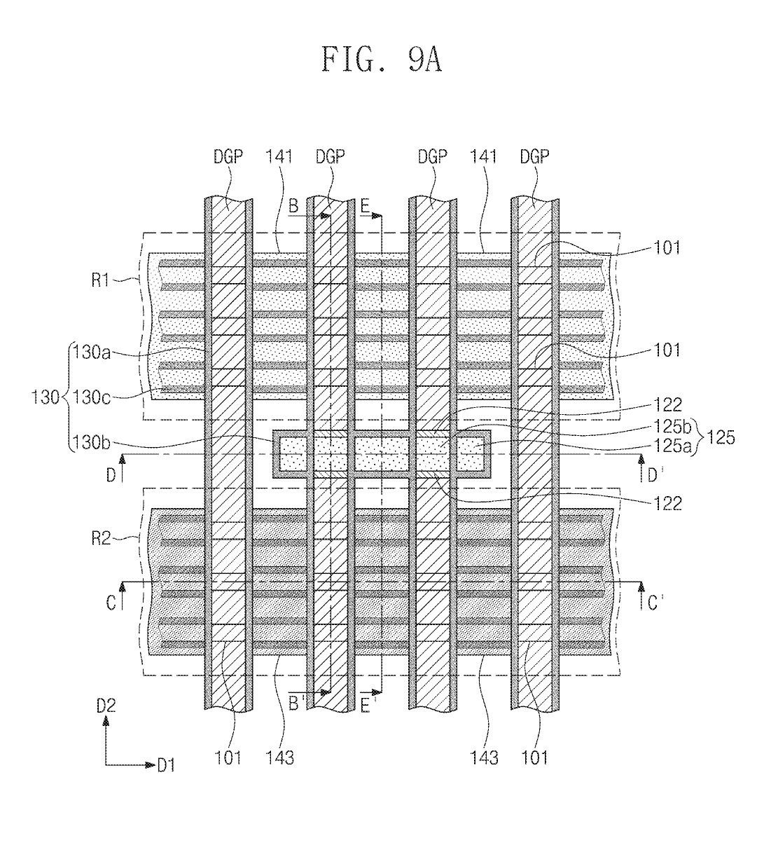

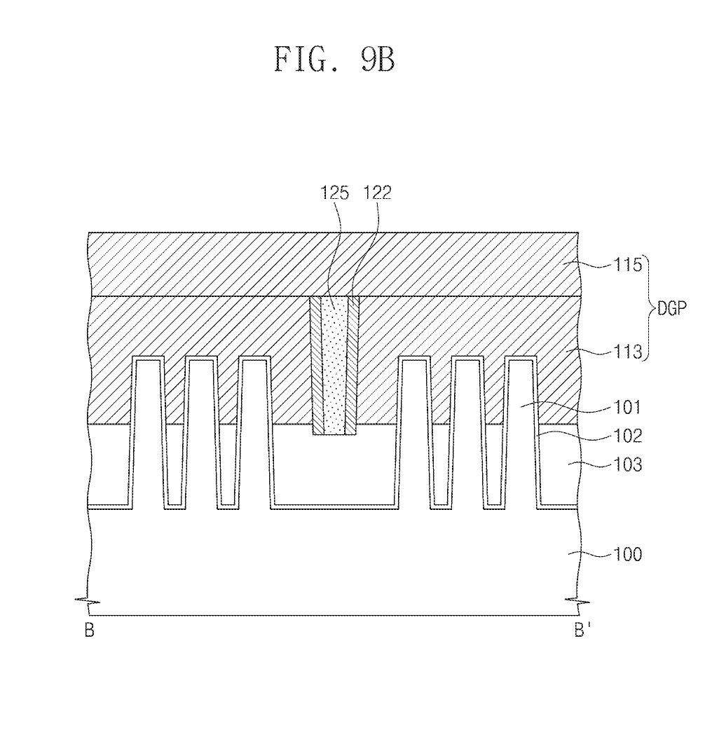

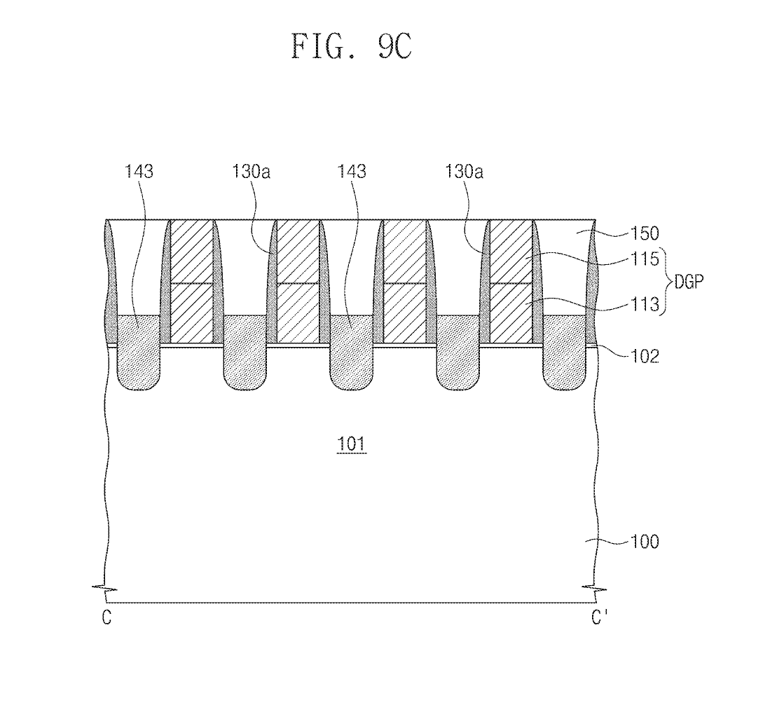

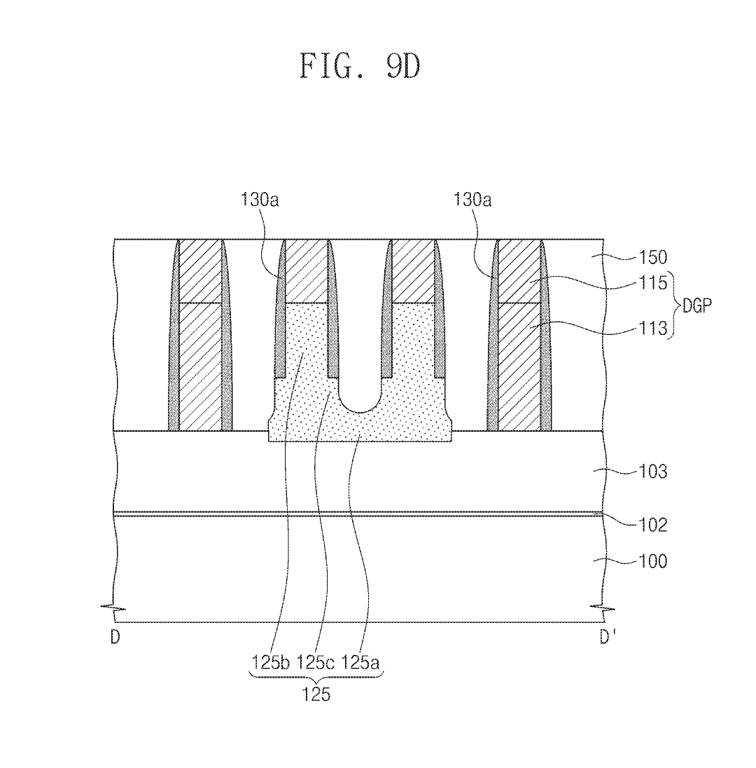

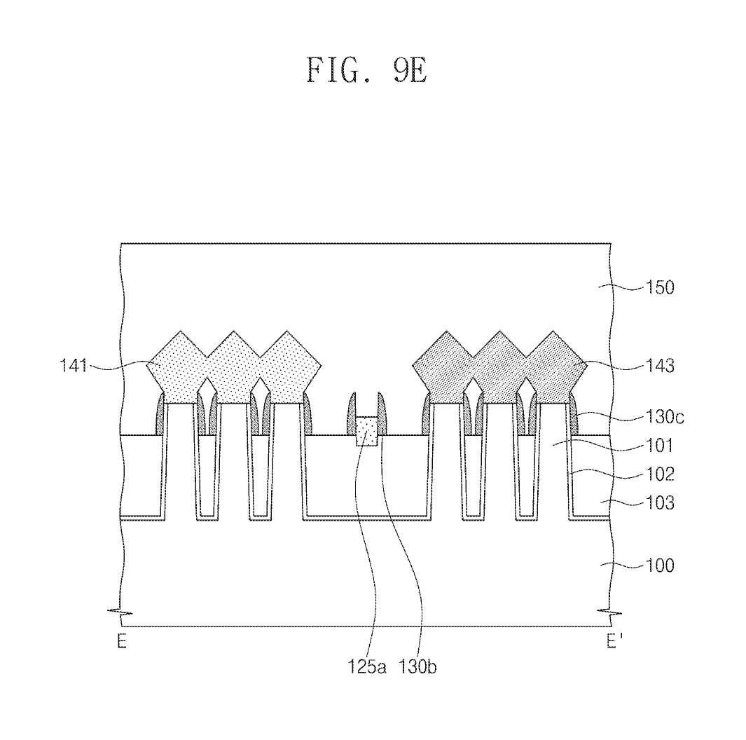

Referring to FIGS. 9A to 9E, first epitaxial layers 141 may be formed in the recessions RS of the first well region R1, and second epitaxial layers 143 may be formed in the recessions RS of the second well region R2.

In some example embodiments, the formation of the first epitaxial layers 141 may be followed by the formation of the second epitaxial layers 143, and the first epitaxial layers 141 may be spaced apart in the second direction D2 from the second epitaxial layers 143. The first and second epitaxial layers 141 and 143 may be formed by performing a selective epitaxial growth process in which the active patterns 101 exposed to the recessions RS are used as seed layers. Each of the first and second epitaxial layers 141 and 143 may include a semiconductor material whose lattice constant is different from that of the semiconductor substrate 100, and may be formed to have a multi-epitaxial layer. The first epitaxial layers 141 may serve as source/drain electrodes of NMOSFETs, and the second epitaxial layers 143 may serve as source/drain electrodes of PMOSFETs. For example, the first epitaxial layers 141 may be formed of a material, for example, silicon carbide (SiC), capable of providing tensile strain to the active patterns 101 below the dummy gate patterns DGP. The second epitaxial layers 143 may be formed of a material, for example, silicon germanium (SiGe), capable of providing compressive strain to the active patterns 101 below the dummy gate patterns DGP.

Optionally, the first and second epitaxial layers 141 and 143 may be provided thereon with a silicide layer (not shown) such as nickel silicide, cobalt silicide, tungsten silicide, titanium silicide, niobium silicide, or tantalum silicide.

After the first and second epitaxial layers 141 and 143 are formed, a first interlayer dielectric layer 150 may be formed to fill between the dummy gate patterns DGP. The first interlayer dielectric layer 150 may have a top surface at substantially the same level as those of top surfaces of the dummy gate patterns DGP. The first interlayer dielectric layer 150 may include one or more of a silicon oxide layer, a silicon nitride layer, a silicon oxynitride layer, and a low-k dielectric layer.

Referring to FIGS. 10A to 10F, the dummy gate patterns DGP may be removed to form gate regions GR defined by the gate spacers 130 and the gate separation pattern 125. The removal of the dummy gate patterns DGP may be achieved by performing dry and/or wet etching processes.

For example, the dummy gate patterns DGP may be wet-etched using an etching recipe exhibiting etch selectivity to the dummy gate patterns DGP and the gate spacers 130. When the dummy gate patterns DGP are formed of a polysilicon layer, polysilicon may be wet-etched using an etchant within which nitric acid, acetic acid, and hydrofluoric acid are mixed with one another.

The gate regions GR may expose sidewalls of the gate spacers 130 and the sidewalls of the upper portions 125b of the gate separation pattern 125. The buffer insulation layer 102 on the active patterns 101 may also be partially removed simultaneously with the removal of the dummy gate patterns DGP, with the result that the active patterns 101 may be exposed on their top surfaces and sidewalls, and the device isolation layer 103 may be exposed on its portion between the active patterns 101. Each of the gate regions GR may have a smaller vertical depth on the active pattern 101 and a greater vertical depth on the device isolation layer 103.

In some example embodiments, in the etching process for forming the gate regions GR, the first dummy gate layer 113 or the dummy spacer pattern 122 may be incompletely etched to locally leave residual dummy gate patterns 113R on lower corners of the gate regions GR, as illustrated in FIGS. 10A and 10F. The residual dummy gate patterns 113R may therefore locally remain between the gate spacer 130 and the gate separation pattern 125 and between the gate spacer 130 and the active patterns 101.

In some example embodiments, when the dummy spacer patterns 122 include the same material as those of the dummy gate patterns DGP, the dummy spacer patterns 122 may also be removed when the dummy gate patterns DGP are removed. Alternatively, when the dummy spacer patterns 122 include a material exhibiting etch selectivity to the dummy gate patterns DGP, the dummy spacer patterns 122 may be exposed to the gate regions GR.

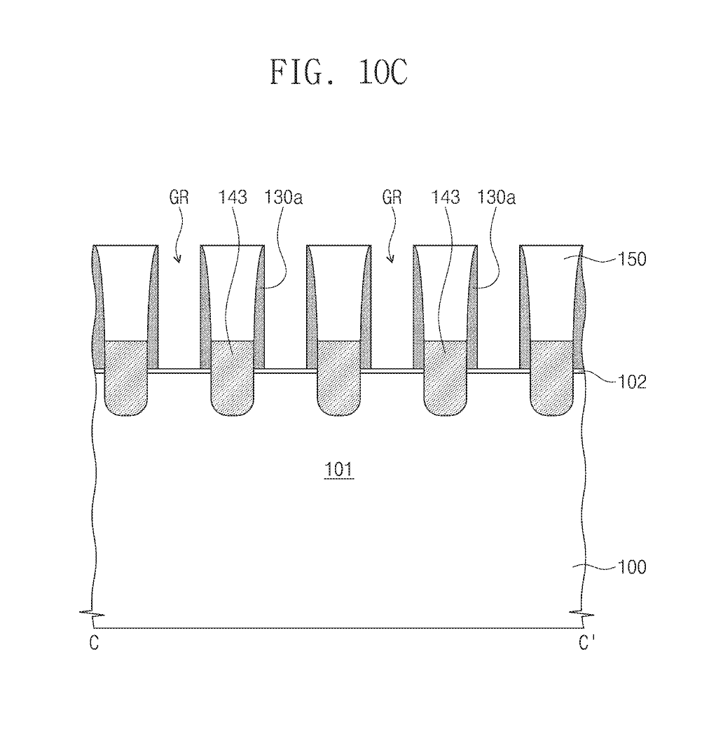

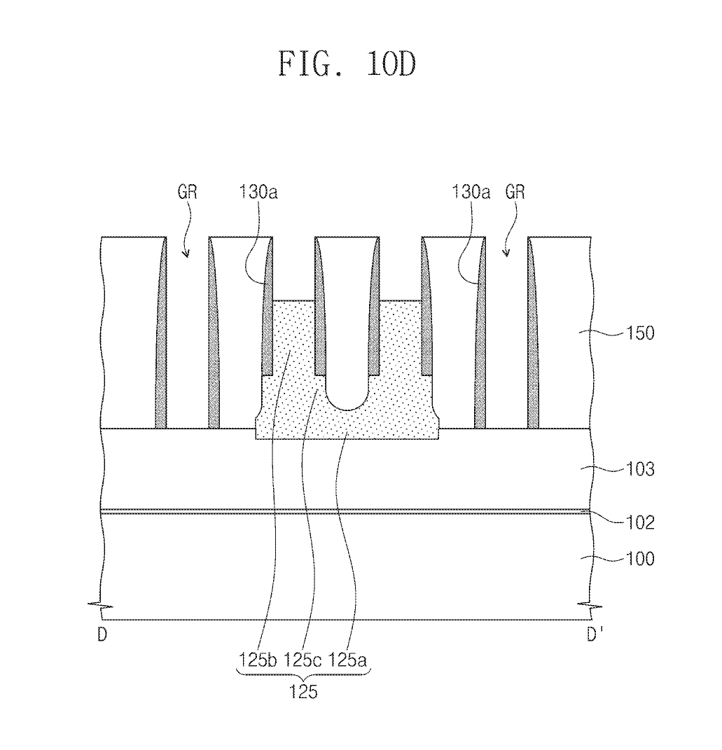

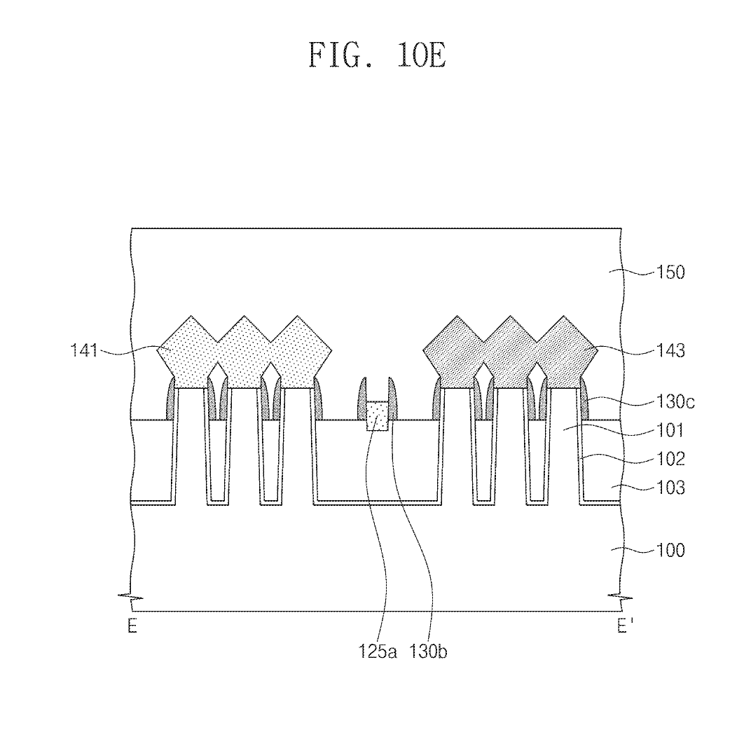

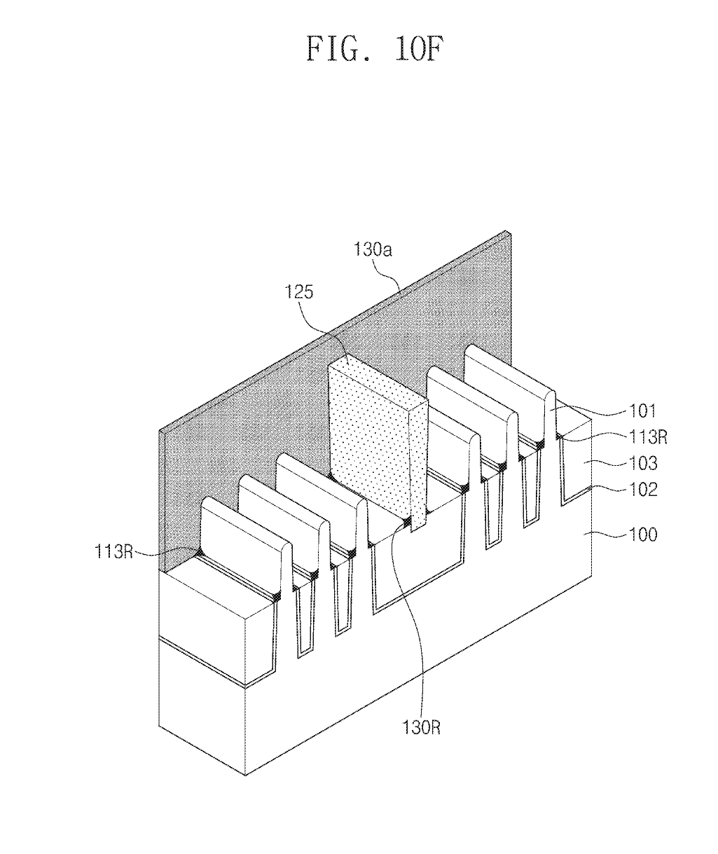

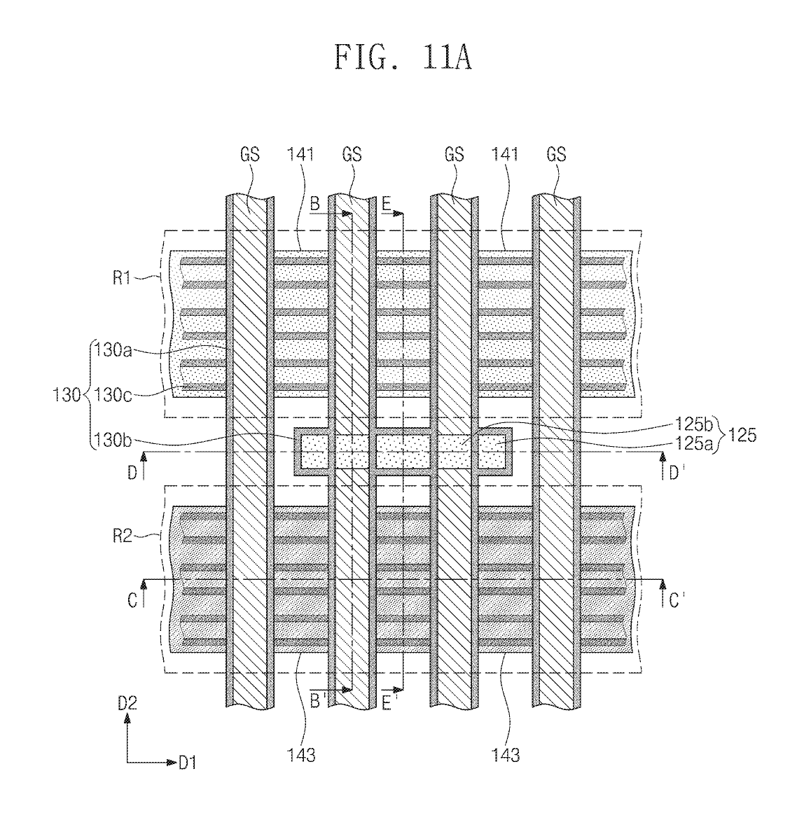

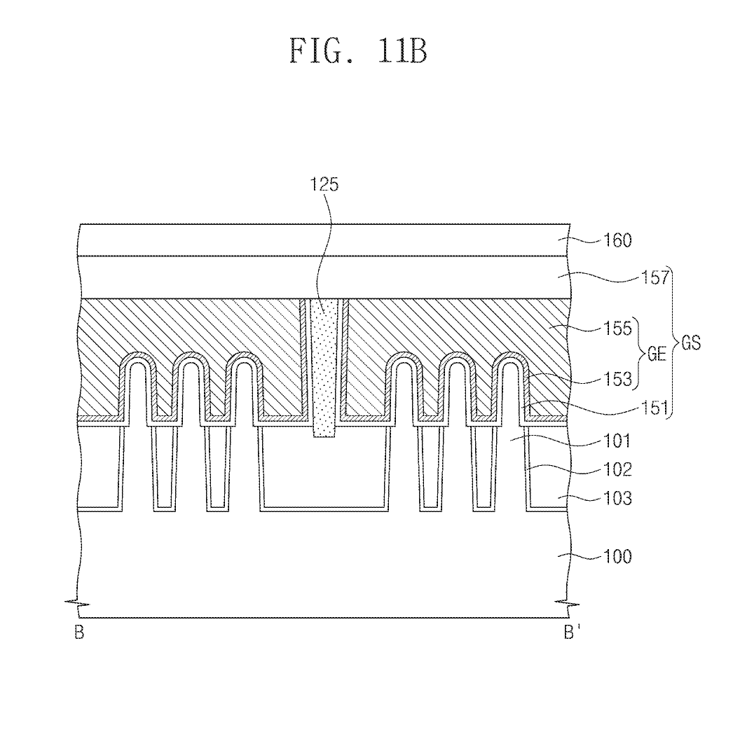

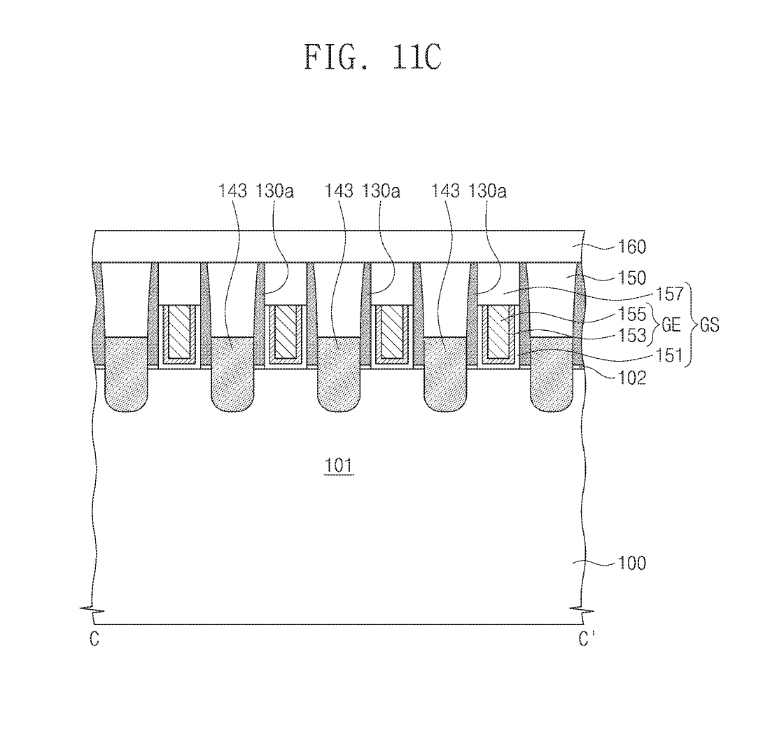

Referring to FIGS. 11A to 11E, gate structures GS may be formed in corresponding gate regions GR.

Each of the gate structures GS may include a gate dielectric layer 151, a gate barrier metal pattern 153, a gate metal pattern 155, and a capping insulation pattern 157.

The gate dielectric layer 151 may be formed of a high-k dielectric layer such as hafnium oxide, hafnium silicate, zirconium oxide, or zirconium silicate. Atomic layer deposition technology may be employed to form the gate dielectric layer 151 conformally covering the surfaces of the active patterns 101, the inner sidewalls of the gate spacers 130 exposed to the gate regions GR, and the sidewall of the gate separation pattern 125. Alternatively, the gate dielectric layer 151 may be formed when the active pattern 101 is thermally oxidized on a surface exposed to the gate regions GR.

The gate barrier metal pattern 153 may be between the gate dielectric layer 151 and the gate metal pattern 155, and may extend between the gate metal pattern 155 and the gate spacers 130. The gate barrier metal pattern 153 may include conductive metal nitride (e.g., titanium nitride, tantalum nitride, and/or tungsten nitride). The gate metal pattern 155 may include a metallic material (e.g., tungsten, titanium, and/or tantalum). The capping insulation pattern 157 may cover a top surface of the gate metal pattern 155. The capping insulation pattern 157 may also cover top surfaces of the gate spacers 130. The capping insulation patterns 157 may have top surfaces substantially coplanar with that of the first interlayer dielectric layer 150. The capping insulation patterns 157 may include, for example, at least one of silicon oxide, silicon nitride, silicon oxynitride, silicon carbon nitride (SiCN), or silicon carbon oxynitride (SiCON).

The gate separation pattern 125 may separate ones of the gate structures GS from each other in the second direction D2. In some example embodiments, since the dummy spacer pattern 122 is removed together with the dummy gate patterns DGP when the gate regions GR are formed, a distance in the second direction D2 between the gate structures GS may be less than a distance in the second direction D2 between the dummy gate patterns DGP.

After the gate structures GS are formed, a second interlayer dielectric layer 160 may be formed on the entire surface of the semiconductor substrate 100. The second interlayer dielectric layer 160 may cover the top surface of the first interlayer dielectric layer 150 and top surfaces of the gate structures GS.

Referring to FIGS. 12A to 12F, a first active contact pattern 170a may be formed to come into contact with a corresponding one of the first and second epitaxial layers 141 and 143, and a second active contact pattern 170b may be formed to connect the first and second epitaxial layers 141 and 143.

The first and second active contact patterns 170a and 170b may penetrate the first and second interlayer dielectric layers 150 and 160. Each of the first and second active contact patterns 170a and 170b may include a barrier metal layer 171 and a metal layer 173, and the barrier metal layer 171 may have a uniform thickness and conformally cover top surfaces of the first and second epitaxial layers 141 and 143.

The second active contact pattern 170b may extend in the second direction D2 from on the first epitaxial layer 141 onto the second epitaxial layer 143, and cross over the lower portion 125a of the gate separation pattern 125.

The second active contact pattern 170b may have a bottom surface, and the height of the lower portion 125a of the gate separation pattern 125 may change the level of the bottom surface between the first and second epitaxial layers 141 and 143. Between the first and second epitaxial layers 141 and 143, the second active contact pattern 170b may cross over the lower portion 125a of the gate separation pattern 125. In other embodiments, the second contact pattern 170b may be in contact with the top surface of the lower portion 125a of the gate separation pattern 125.

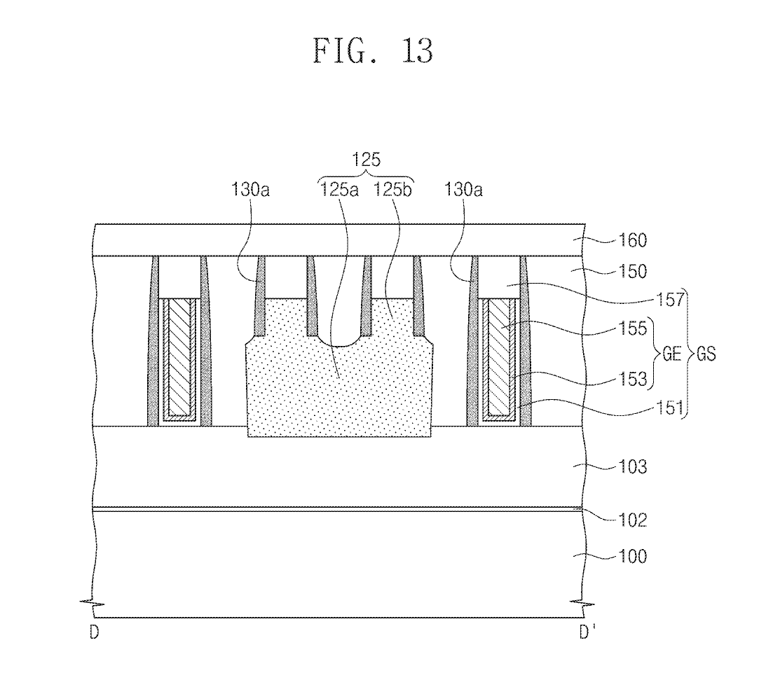

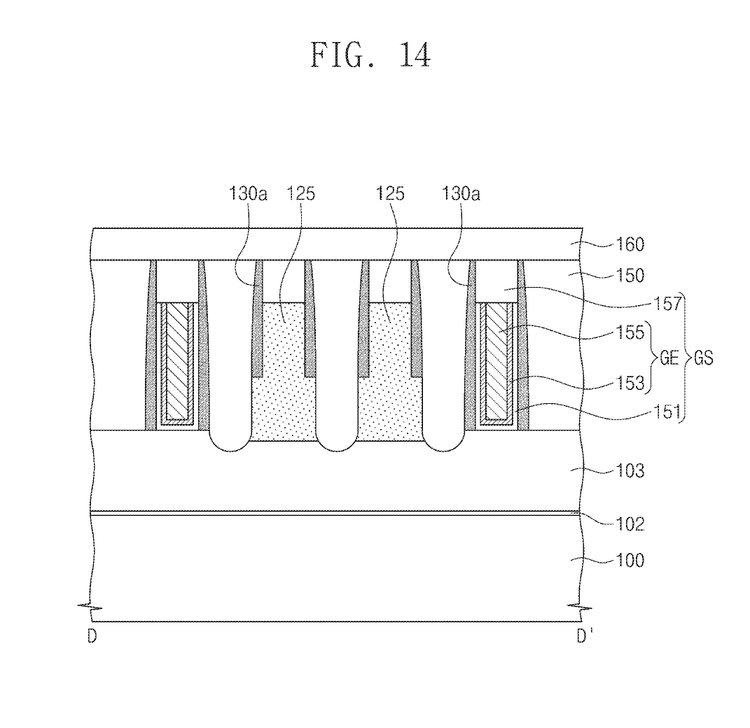

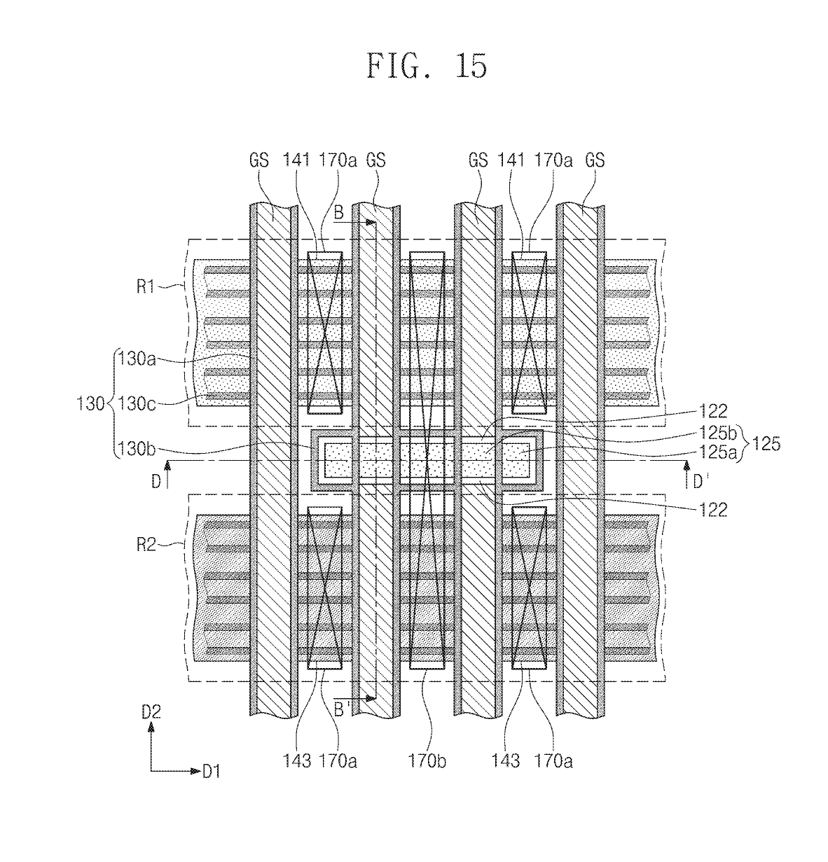

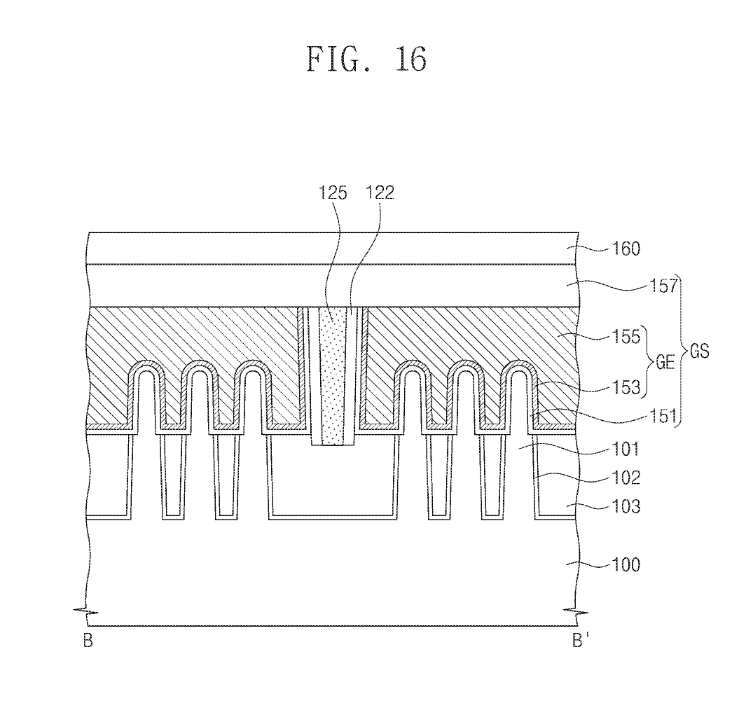

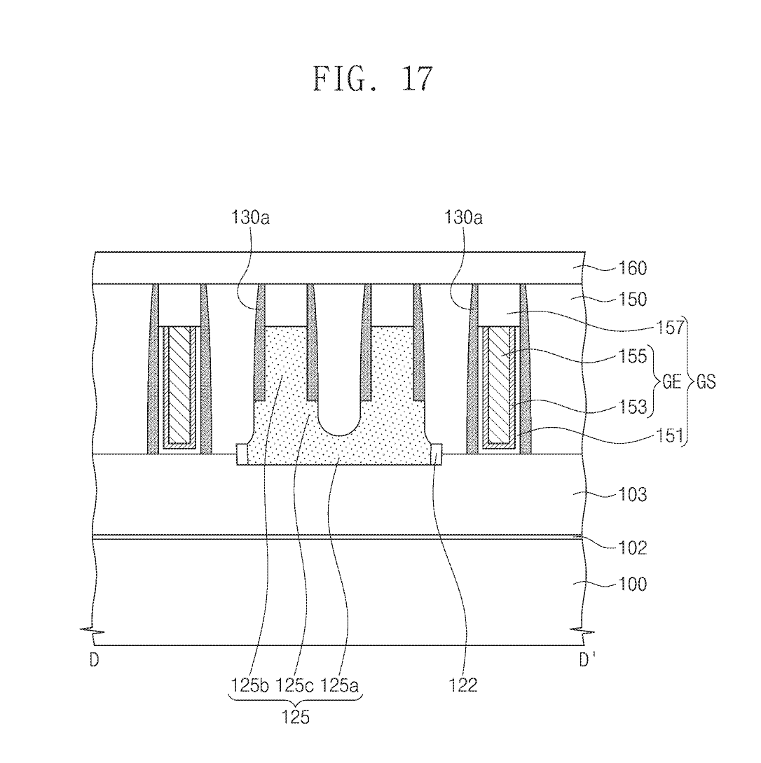

FIGS. 13, 14, and 15 illustrate cross-sectional and plan views showing a method of fabricating a semiconductor device according to some example embodiments of inventive concepts. FIGS. 16 and 17 illustrate cross-sectional views respectively taken along lines B-B′ and D-D′ of FIG. 15.

For brevity of explanation, a detailed description of technical features the same as those of the semiconductor device discussed above may be omitted, and a difference thereof will be described.

In the embodiment illustrated in FIG. 13, the gate separation pattern 125 may include no intermediate portion, and include the lower portion 125a extending in the first direction D1 and the upper portions 125b protruding from the lower portion 125a. Each of the upper portions 125b may have substantially the same width as those of the gate structures GS. The top surface of the lower portion 125a may be located at a greater level than that of the bottom surface of the second active contact pattern 170b.

In the example embodiment illustrated in FIG. 14, when the etching process is performed to form the recessions RS discussed with reference to FIGS. 8A to 8E, a lower portion of the preliminary gate-separation pattern 124 may be etched to expose the device isolation layer 103. The above process may form the gate separation patterns 125 spaced apart from each other in the first direction D1.

In the example embodiment as illustrated in FIGS. 15-17, as discussed above with reference to FIGS. 4A to 4E, the dummy spacer 121 may be formed of a material exhibiting etch selectivity to the first dummy gate layer 113. In this case, as discussed with reference to FIGS. 10A to 10E, when the gate regions GR are formed, the dummy spacer pattern 122 may remain without being removed. For example, the dummy spacer patterns 122 may remain between the gate separation pattern 125 and the gate structures GS. Therefore, the gate separation pattern 125 and the dummy spacer patterns 122 may be between the gate structures GS adjacent in the second direction D2 to each other.

According to some example embodiments of inventive concepts, the formation of dummy gate patterns may be preceded by the formation of a gate separation pattern separating gate electrode structures. Increasing a process margin for the formation of the gate separation pattern may thus be possible.

The formation of the gate separation pattern may be preceded by the formation of a dummy spacer covering the sidewall of an opening, which sequence may decrease the width of the gate separation pattern. In this case, since gate electrodes decrease in interval therebetween, a semiconductor device may increase in integration.

A low-k dielectric material is adopted to form gate spacers covering the sidewalls of the gate electrode structures and crossing over the gate separation pattern, and as a result, capacitive coupling may be reduced between the gate electrode structures adjacent to each other.

Although inventive concepts have been described in connection with example embodiments of inventive concepts illustrated in the accompanying drawings, those skilled in the art will understand that various changes and modifications may be made without departing from the technical spirit and essential feature of inventive concepts. It will be apparent to those skilled in the art that various substitution, modifications, and changes may be thereto without departing from the scope and spirit of the inventive concepts.

What is claimed is:

1. A semiconductor device, comprising:
a semiconductor substrate including active patterns extending in a first direction;
a plurality of gate electrodes crossing the active patterns and extending in a second direction, the gate electrodes spaced apart in the second direction from each other;
a gate separation pattern having a major axis in the first direction and between two of the gate electrodes, the two of the gate electrodes adjacent to each other in the second direction; and
a plurality of gate spacers covering sidewalls of respective ones of the gate electrodes, the gate spacers crossing the gate separation pattern and extending in the second direction,
wherein the gate separation pattern includes,
a lower portion extending in the first direction,
an intermediate portion protruding from the lower portion and having a first width, and
an upper portion between two adjacent gate spacers and protruding from the intermediate portion, the upper portion having a second width less than the first width.

2. The device of claim 1, wherein each of the gate electrodes has a width substantially the same as the second width.

3. The device of claim 1, wherein each of the gate spacers comprises a low-k dielectric material having a dielectric constant less than that of the gate separation pattern.

4. The device of claim 1, wherein the gate spacers comprise:
a first spacer portion extending in the second direction and covering the sidewalls of the gate electrodes and a sidewall of the upper portion of the gate separation pattern; and
a second spacer portion extending in the first direction and covering a sidewall of the lower portion of the gate separation pattern.

5. The device of claim 4, wherein a height of the first spacer portion is greater than a height of the second spacer portion.

6. The device of claim 1, wherein a top surface of the upper portion of the gate separation pattern is at substantially the same level as those of top surfaces of the gate electrodes.

7. The device of claim 1, wherein a bottom surface of the gate separation pattern is at a lower level than those of bottom surfaces of the gate electrodes.

8. The device of claim 1, further comprising:
a plurality of residual dummy gate patterns locally on corresponding lower corners of the gate electrodes,
wherein the residual dummy gate patterns include different materials from those of the gate electrodes.

9. The device of claim 1, wherein each of the gate electrodes comprises:
a metal pattern; and
a barrier metal pattern between the metal pattern and the active patterns and extending between the metal pattern and the gate spacers.

10. The device of claim 1, further comprising:
a plurality of epitaxial layers on the active patterns between opposite sides of each of the gate electrodes,
wherein a portion of the gate separation pattern is between the epitaxial layers, the epitaxial layers being spaced apart in the second direction from each other.

11. The device of claim 10, further comprising:
a contact pattern connecting the epitaxial layers,
wherein a portion of the contact pattern runs across the lower portion of the gate separation pattern.

12. A semiconductor device, comprising:
a semiconductor substrate including active patterns extending in a first direction;
a plurality of gate electrodes crossing the active patterns and extending in a second direction, the gate electrodes spaced apart in the second direction from each other;
a gate separation pattern between at least two gate electrodes of the plurality of gate electrodes, the at least two gate electrodes adjacent to each other in the second direction, the gate separation pattern having a major axis in the first direction; and
a plurality of gate spacers covering sidewalls of respective ones of the gate electrodes, the gate spacers crossing the gate separation pattern and extending in the second direction,
wherein the gate separation pattern includes,
an upper portion between two adjacent ones of the gate spacers, and
a lower portion extending in the first direction below the gate spacers,
wherein each of the gate spacers includes a low-k dielectric material having a dielectric constant less than that of the gate separation pattern.

13. The device of claim 12, wherein the gate spacers comprise:
a first spacer portion extending in the second direction and covering the sidewalls of one of the gate electrodes and a sidewall of the upper portion of the gate separation pattern; and
a second spacer portion extending in the first direction and covering a sidewall of the lower portion of the gate separation pattern.

14. The device of claim 13, wherein a height of the first spacer portion is greater than a height of the second spacer portion.

15. The device of claim 12, wherein each of the gate electrodes has substantially the same width as that of the upper portion of the gate separation pattern.

16. The device of claim 12, wherein top surfaces of the gate electrodes are at substantially the same level as that of a top surface of the upper portion of the gate separation pattern.

17. A semiconductor device, comprising:
a semiconductor substrate including a first active pattern and a second active pattern, the first active pattern and the second active pattern extending in a first direction;
a plurality of first gate electrodes crossing the first active pattern and extending in a second direction;
a plurality of second gate electrodes crossing the second active pattern and extending in the second direction, the second gate electrodes spaced apart from the first gate electrodes in the second direction;
a gate separation pattern between one of the first gate electrodes and one of the second gate electrodes, the one of the first gate electrode and the one of the second gate electrode being adjacent to each other in the second direction;
a plurality of gate spacers extending along the second direction from sidewalls of respective ones of the first gate electrodes and the second gate electrodes;
a plurality of first epitaxial layers on the first active pattern and between the first gate electrodes; and
a plurality of second epitaxial layers on the second active pattern and between the second gate electrodes,
wherein the gate separation pattern includes,
a plurality of first portions each having a first height between the one of the first gate electrodes and the one of the second gate electrodes, and
a plurality of second portions connected in the first direction to the first portions and positioned in the second direction between one of the first epitaxial layers and one of the second epitaxial layers,
wherein each of the second portions has a second height less than the first height.

18. The device of claim 17, further comprising:
a contact pattern connecting the first and second epitaxial layers,
wherein the contact pattern runs across one of the second portions of the gate separation pattern.

19. The device of claim 17, wherein each of the gate spacers comprises a low-k dielectric material having a dielectric constant less than that of the gate separation pattern.

20. The device of claim 17, wherein each of the first portions of the gate separation pattern comprises:
an upper portion having the same width as those of the first and second gate electrodes; and
an intermediate portion having a width greater than that of the upper portion.
